(19) United States
(12) Patent Application Publication
(10) Pub. No.: US 2026/0006998 A1
(43) Pub. Date: Jan. 1, 2026

(54) DISPLAY PANEL AND ELECTRONIC DEVICE

(71) Applicant: Samsung Display Co., Ltd., Yongin-si (KR)

(72) Inventors: KEUNWOO PARK, Yongin-si (KR); MIN-JAE KIM, Yongin-si (KR); KYUNGHAE PARK, Yongin-si (KR); JAE CHEOL PARK, Yongin-si (KR); GAK SEOK LEE, Yongin-si (KR)

(73) Assignee: Samsung Display Co., Ltd., Yongin-si (KR)

(21) Appl. No.: 19/176,522

(22) Filed: Apr. 11, 2025

(30) Foreign Application Priority Data
Jun. 26, 2024 (KR) 10-2024-0083444

(51) Int. Cl. H10K 59/122; H10K 59/38; H10K 59/80

(52) U.S. Cl. CPC H10K 59/122; H10K 59/38; H10K 59/873

(57) ABSTRACT

A display panel includes a display element layer including a light emitting element which outputs source light, and an optical structure layer which is disposed on the light emitting element and transmits the source light or converts the source light to light having a different wavelength range. The optical structure layer includes a light control layer disposed on the light emitting element, and the light control layer includes a bank defining a bank opening portion, a light control pattern disposed in the bank opening portion, and a metal pattern disposed between the bank and the light control pattern. The bank is optically transparent, the metal pattern surrounds a portion of the light control pattern in a plan view, and the metal pattern defines an open portion which does not surround the light control pattern.

### CROSS-REFERENCE TO RELATED APPLICATION(S)

This application claims priority to and benefits of Korean Patent Application No. 10-2024-0083444 under 35 U.S.C. § 119, filed on Jun. 26, 2024, the entire contents of which are incorporated herein by reference.

### BACKGROUND

### 1. Technical Field

Embodiments relate to a display panel, for example, a display panel that provides increased resolution and improved display efficiency.

### 2. Description of the Related Art

An electronic device includes a display panel that displays an image. A display panel includes a transmissive display panel, which selectively transmits source light generated from a light source, or an emissive display panel, which generates source light in the display panel itself. The display panels may include various light control patterns associated with pixels to generate a color image. A light control pattern may transmit a portion of a wavelength range of the source light or convert a color of the source light. Some portions of the light control pattern may not alter the color of the source light but may modify its characteristics.

### SUMMARY

The disclosure provides a display panel capable of realizing high resolution and having improved display efficiency.

An embodiment provides a display panel including a display element layer including a light emitting element which outputs source light, and an optical structure layer disposed on the light emitting element that transmits the source light or converts the source light to light having a different wavelength range. The optical structure layer may include a light control layer disposed on the light emitting element. The light control layer may include a bank defining a bank opening portion, a light control pattern disposed in the bank opening portion, and a metal pattern disposed between the bank and the light control pattern. The bank may be optically transparent, the metal pattern may surround a portion of the light control pattern in a plan view, and the metal pattern may define an open portion which does not surround the light control pattern.

In an embodiment, the bank may include a material having a transmittance of about 85% or more in a visible light range.

In an embodiment, the light control pattern in the open portion may be in contact with at least a portion of the bank.

In an embodiment, the metal pattern may include a first portion disposed on an inner side surface of the bank, and a second portion extending from the first portion and covering at least a portion of an upper surface of the bank.

In an embodiment, the bank opening portion may include a first bank opening portion and a second bank opening portion which are adjacent to each other in a first direction, and the light control pattern may include a first light control pattern disposed in the first bank opening portion, and a second light control pattern disposed in the second bank opening portion.

In an embodiment, the metal pattern may include a first metal pattern which is disposed between the bank and the first light control pattern and surrounds a portion of the first light control pattern, and a second metal pattern which is disposed between the bank and the second light control pattern and surrounds a portion of the second light control pattern. The first metal pattern may define a first open portion which does not surround the first light control pattern, and the second metal pattern may define a second open portion which does not surround the second light control pattern.

In an embodiment, the first open portion and the second open portion may not face each other in the first direction.

In an embodiment, between the first light control pattern and the second light control pattern, the first open portion and at least a portion of the second metal pattern may face each other, or the second open portion and at least a portion of the first metal pattern may face each other.

In an embodiment, in the first open portion, the first light control pattern may be in contact with at least a portion of the bank, and in the second open portion, the second light control pattern may be in contact with at least a portion of the bank.

In an embodiment, one of the first metal pattern and the second metal pattern may be disposed between the first light control pattern and the second light control pattern.

In an embodiment, a first bank area defined by the first bank opening portion may emit light having a first wavelength, and a second bank area defined by the second bank opening portion may emit light having a second wavelength. The second wavelength may be shorter than the first wavelength.

In an embodiment, the bank opening portion may further include a third bank opening portion adjacent to the second bank opening portion in the first direction, and the light control layer may further include a third light control pattern disposed in the third bank opening portion.

In an embodiment, the metal pattern may include a first metal pattern which is disposed between the bank and the first light control pattern and surrounds a portion of the first light control pattern, a second metal pattern which is disposed between the bank and the second light control pattern and surrounds a portion of the second light control pattern, and a third metal pattern which is disposed between the bank and the third light control pattern and surrounds a portion of the third light control pattern. The first metal pattern may define a first open portion which does not surround the first light control pattern, the second metal pattern may define a second open portion which does not surround the second light control pattern, and the third metal pattern may define a third open portion which does not surround the third light control pattern.

In an embodiment, one of the first metal pattern and the second metal pattern may be disposed between the first light control pattern and the second light control pattern, one of the second metal pattern and the third metal pattern may be disposed between the second light control pattern and the third light control pattern, and one of the third metal pattern and the first metal pattern may be disposed between the third light control pattern and the first light control pattern.

In an embodiment, the second metal pattern may be disposed between the first light control pattern and the second light control pattern, the second metal pattern may be disposed between the second light control pattern and the third light control pattern, and the third metal pattern may be disposed between the third light control pattern and the first light control pattern.

In an embodiment, each of the first light control pattern and the second light control pattern may include a base resin and a quantum dot dispersed in the base resin, and the first light control pattern may include a photosensitive resin.

In an embodiment, the optical structure layer may further include a color filter layer disposed on the light control layer and including a first color filter, a second color filter, and a third color filter. The first color filter may overlap at least the first light control pattern in a plan view, the second color filter may overlap at least the second light control pattern in a plan view, and the third color filter may overlap at least the third light control pattern in a plan view.

In an embodiment, the light control layer may further include a first barrier layer which covers a surface of each of the first light control pattern, the second light control pattern, and the third light control pattern.

In an embodiment, the display element layer may further include an encapsulation layer which covers the light emitting element, and the light control layer may be directly disposed on the encapsulation layer.

In an embodiment, a display panel may include a display element layer including a light emitting element which outputs source light, and an optical structure layer which is disposed on the light emitting element and transmits the source light or converts the source light to light having a different wavelength range. The optical structure layer may include a light control layer disposed on the light emitting element, and the light control layer may include a bank including a first bank opening portion and a second bank opening portion which are adjacent to each other in a first direction, a first light control pattern disposed in the first bank opening portion, a second light control pattern disposed in the second bank opening portion, a first metal pattern disposed between the bank and the first light control pattern, and a second metal pattern disposed between the bank and the second light control pattern. The bank may include a first inner side surface which defines the first bank opening portion, and a second inner side surface which defines the second bank opening portion. The first metal pattern may define a first open portion which exposes at least a portion of the first inner side surface, the second metal pattern may define a second open portion which exposes at least a portion of the second inner side surface, and the first open portion and the second open portion may not face each other.

In an embodiment, an electronic device may include a window, a display panel disposed below the window, and a housing disposed below the display panel and coupled with the window to accommodate the display panel. The display panel may include a display element layer comprising a light emitting element which outputs source light, and an optical structure layer disposed on the light emitting element, which transmits the source light or converts the source light to light having a different wavelength range. The optical structure layer may include a light control layer disposed on the light emitting element, and the light control layer may include a bank defining a bank opening portion, a light control pattern disposed in the bank opening portion, and a metal pattern disposed between the bank and the light control pattern. The bank may be optically transparent, the metal pattern may surround a portion of the light control pattern in a plan view, and the metal pattern may define an open portion which does not surround the light control pattern.

### BRIEF DESCRIPTION OF THE DRAWINGS

The above and other aspects, features, and advantages of embodiments will be more apparent from the following description taken in conjunction with the accompanying drawings, in which:

FIG. 1A is a schematic perspective view of a display panel according to an embodiment;

FIG. 1B is a schematic cross-sectional view of a display panel according to an embodiment;

FIG. 1C is a schematic plan view of a display panel according to an embodiment;

FIG. 2A is an enlarged schematic plan view of a portion of a display panel according to an embodiment;

FIG. 2B is an enlarged schematic plan view of a display panel corresponding to area AA illustrated in FIG. 2A according to an embodiment;

FIG. 3 is a schematic cross-sectional view of a portion of a display panel according to an embodiment;

FIGS. 4A, 4B, 4C, and 4D are schematic cross-sectional views of a portion of a display panel according to an embodiment;

FIG. 5 is a schematic cross-sectional view of a light emitting element according to an embodiment;

FIG. 6 is an enlarged partial schematic cross-sectional view of some components of a display panel according to an embodiment;

FIGS. 7A, 7B, and 7C are enlarged schematic plan views of a portion of a display panel according to an embodiment;

FIG. 8A is an enlarged schematic plan view of a portion of a display panel according to an embodiment;

FIG. 8B is a schematic cross-sectional view of a portion of a display panel according to an embodiment;

FIG. 9 is a schematic perspective view showing an electronic apparatus according to an embodiment;

FIG. 10 is a schematic exploded perspective view showing an electronic apparatus according to an embodiment;

FIG. 11 is a schematic block diagram of an electronic device according to an embodiment; and

FIG. 12 illustrates schematic views of electronic devices according to various embodiments.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art. Various embodiments do not have to be exclusive nor limit the disclosure. For example, specific shapes, configurations, and characteristics of an embodiment may be used or implemented in another embodiment.

In the drawings, sizes, thicknesses, ratios, and dimensions of the elements may be exaggerated for ease of description and for clarity. Like reference numbers and/or reference characters refer to like elements throughout.

As used herein, the singular forms “a,” “an,” and “the” are intended to include the plural forms as well, unless the context clearly indicates otherwise.

As used herein, the term “about” or “approximately” is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

In the specification and claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

The phrase “in a plan view” means viewing the object from the top, and the phrase “in a schematic cross-sectional view” means viewing a cross-section of which the object is vertically cut from the side. Hence, the expression “in a plan view” used herein may mean that an object is viewed in the third z direction from the top. The phrase “in a schematic cross-sectional view” means viewing a cross-section in the first x direction or the second y direction of which the object is vertically cut from the side. The third z direction also can be referred to as a “thickness direction.”

It will be understood that when an element (or a layer, a region, a portion, or the like) is referred to as “formed on,” “being on,” “disposed on,” “connected to,” or “coupled to” another element in the specification, it can be directly formed on, disposed on, connected or coupled to another element mentioned above, or intervening elements may be disposed therebetween. It will be understood that the terms “connected to” or “coupled to” may include a physical or electrical connection or coupling.

The phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

It will be understood that, although the terms “first,” “second,” etc. may be used herein to describe various elements, these elements should not be limited by these terms. These terms are only used to distinguish one element from another. For example, a first element may be referred to as a second element, and similarly, a second element may be referred to as a first element without departing from the scope of the disclosure.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

As used herein, “directly disposed” may mean that no additional layer, film, region, plate, or the like is positioned between a part, such as a layer, film, region, plate, or the like, and another part. For example, “directly disposed” may refer to two layers or two members disposed without an intervening component, such as an adhesive layer.

Unless otherwise defined, all terms (including technical and scientific terms) used herein have the same meaning as commonly understood by one of ordinary skill in the art to which this disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a display panel and a method for manufacturing the display panel according to an embodiment will be described with reference to the accompanying drawings.

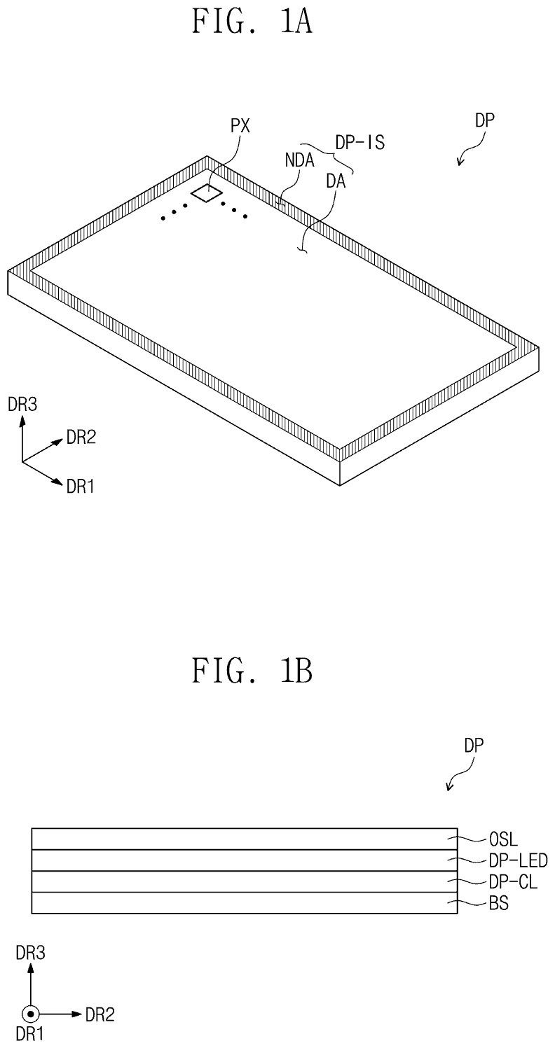

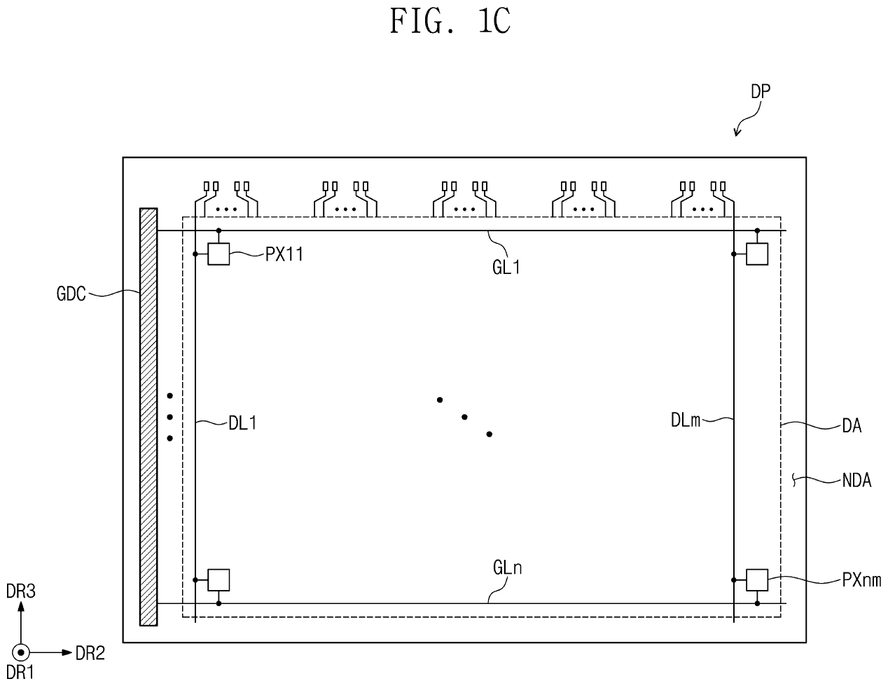

FIG. 1A is a schematic perspective view of a display panel according to an embodiment. FIG. 1B is a schematic cross-sectional view of a display panel according to an embodiment. FIG. 1C is a schematic plan view of a display panel according to an embodiment.

As illustrated in FIG. 1A, a display panel DP may display an image through a display surface DP-IS. The display surface DP-IS may be parallel to a plane defined by a first direction DR1 and a second direction DR2. The display surface DP-IS may include a display area DA and a non-display area NDA. A pixel PX may be disposed on the display area DA, and the pixel PX may not be disposed on the non-display area NDA. The non-display arca NDA may be defined along an edge of the display surface DP-IS. The non-display arca NDA may surround the display area DA. However, an embodiment is not limited thereto, and in an embodiment, the non-display area NDA may be omitted or be disposed at a side of the display arca DA.

A third direction DR3 may indicate a normal direction to the display surface DP-IS, e.g., a thickness direction of the display panel DP. A front surface (or top surface) and a rear surface (or bottom surface) of each of layers or units to be described below may be defined based on the third direction DR3. However, the first to third directions DR1, DR2, and DR3 illustrated in this embodiment are provided as examples.

The display panel DP may include a planar display surface DP-IS, as illustrated in an embodiment, but is not limited thereto. For example, the display panel DP may include a curved display surface or a three-dimensional display surface. The three-dimensional display surface may include multiple display areas oriented in different directions.

As illustrated in FIG. 1B, the display panel DP may include a base substrate BS, a circuit element layer DP-CL, a display element layer DP-LED, and an optical structure layer OSL. The base substrate BS may include a synthetic resin substrate or a glass substrate. The circuit element layer DP-CL may include at least an insulation layer and a circuit element. The circuit element may include a signal line, a driving circuit of a pixel, and the like. The circuit element layer DP-CL may be formed through processes such as forming an insulation layer, a semiconductor layer, and a conductive layer through coating, deposition, or the like, and patterning the insulation layer, the semiconductor layer, and the conductive layer through photolithography. The display element layer DP-LED may include at least a display element. The optical structure layer OSL may convert a color of light provided from the display element. The optical structure layer OSL may include a light control pattern and a structure for increasing photoconversion efficiency.

FIG. 1C illustrates an arrangement of signal lines GL1 to GLn and DL1 to DLm and pixels PX11 to PXnm in a plan view. The signal lines GL1 to GLn and DL1 to DLm may include multiple gate lines GL1 to GLn and multiple data lines DL1 to DLm.

Each of the pixels PX11 to PXnm may be connected to a corresponding gate line among the multiple gate lines GL1-GLn and a corresponding data line among the multiple data lines DL1 to DLm. Each of the pixels PX11 to PXnm may include a pixel driving circuit and a display element. Based on the configuration of the pixel driving circuit of the pixels PX11 to PXnm, additional types of signal lines may be provided in the display panel DP.

A gate driving circuit GDC may be integrated into the display panel DP through an oxide silicon gate (OSG) driver circuit process or an amorphous silicon gate (ASG) driver circuit process.

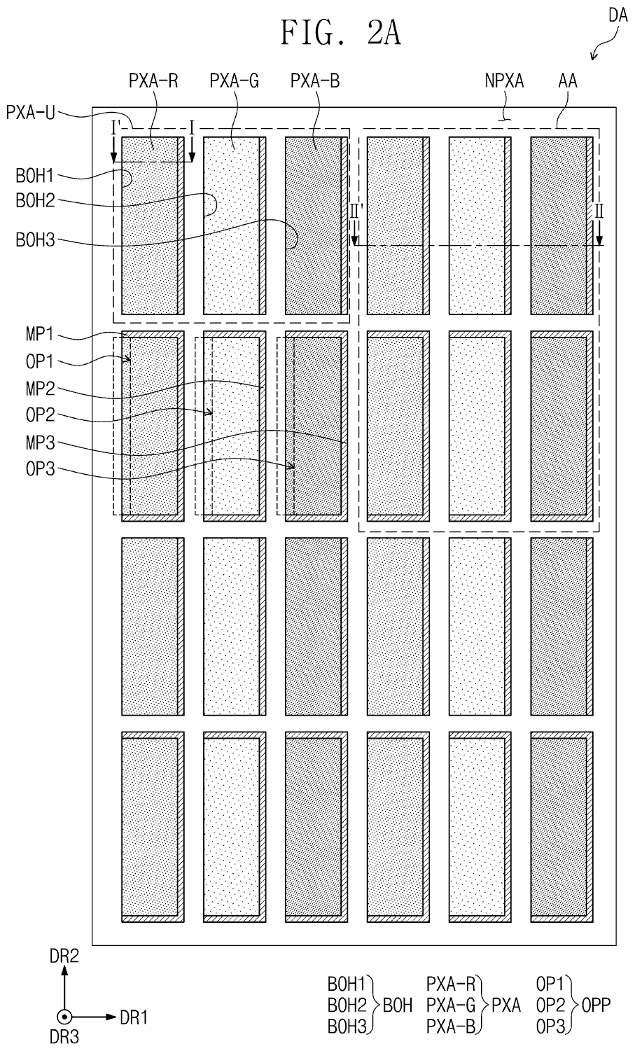

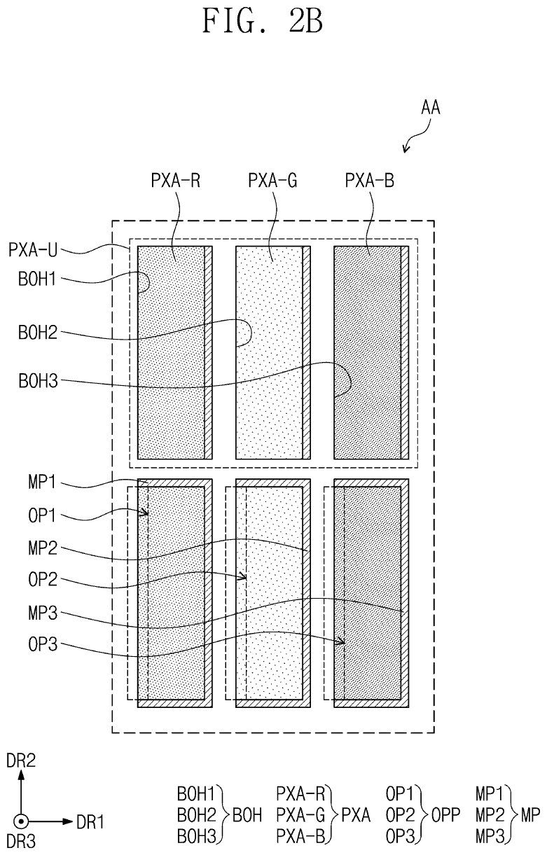

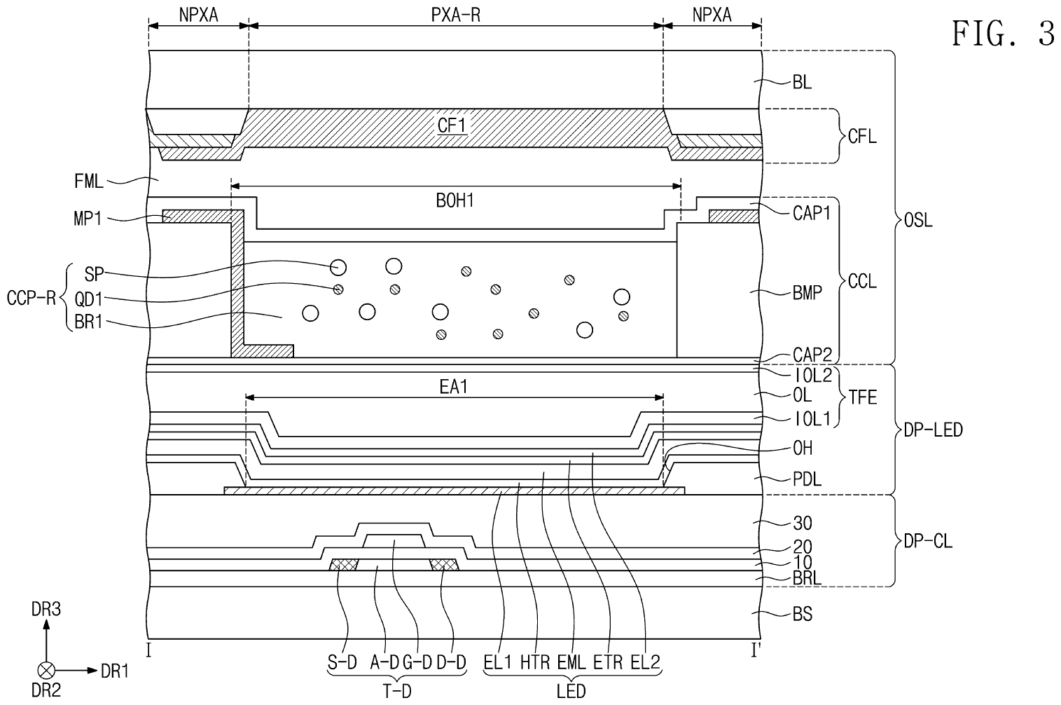

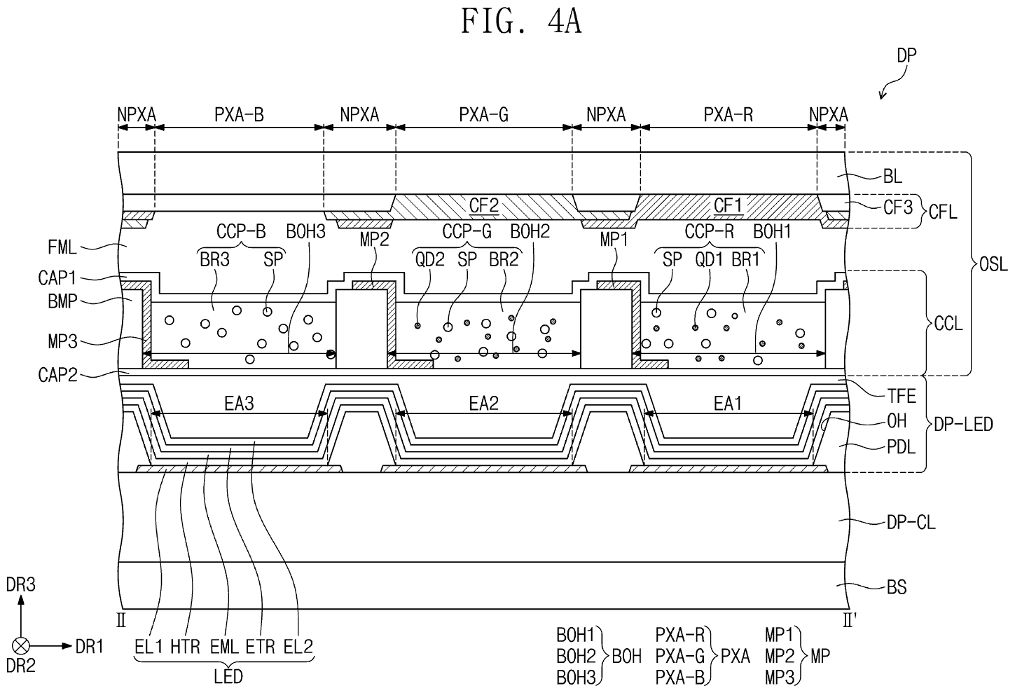

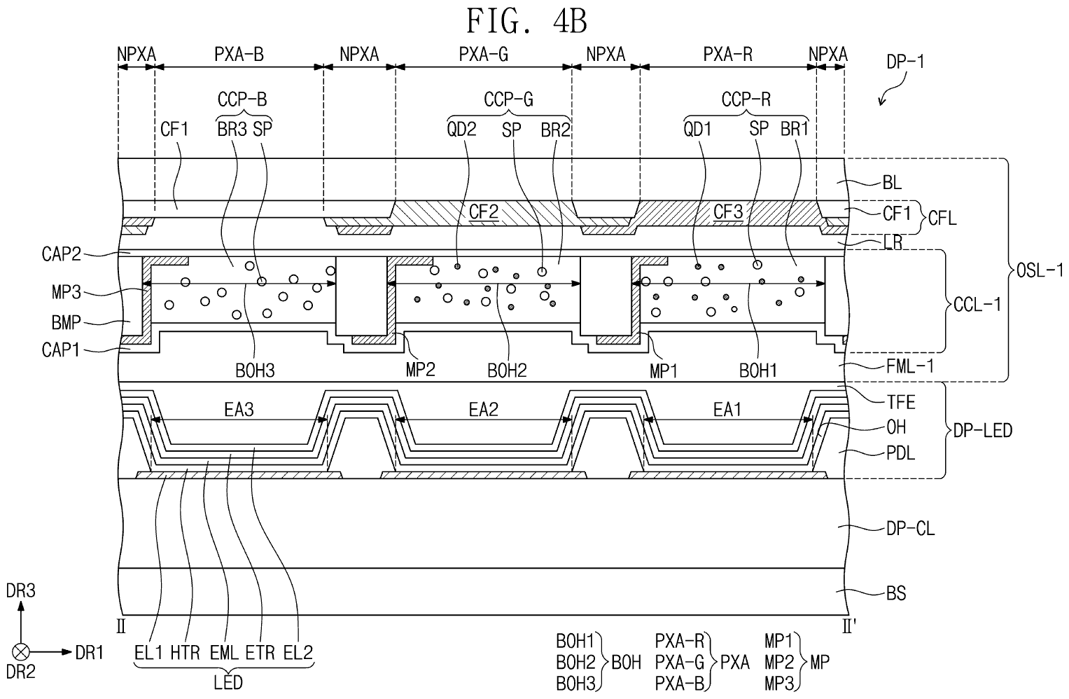

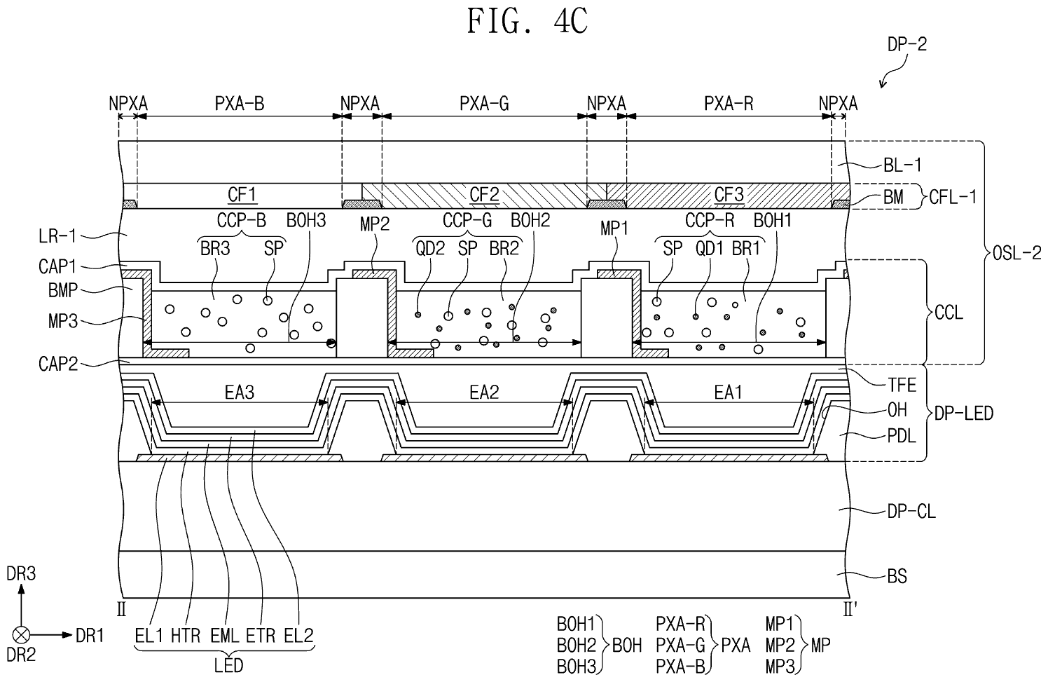

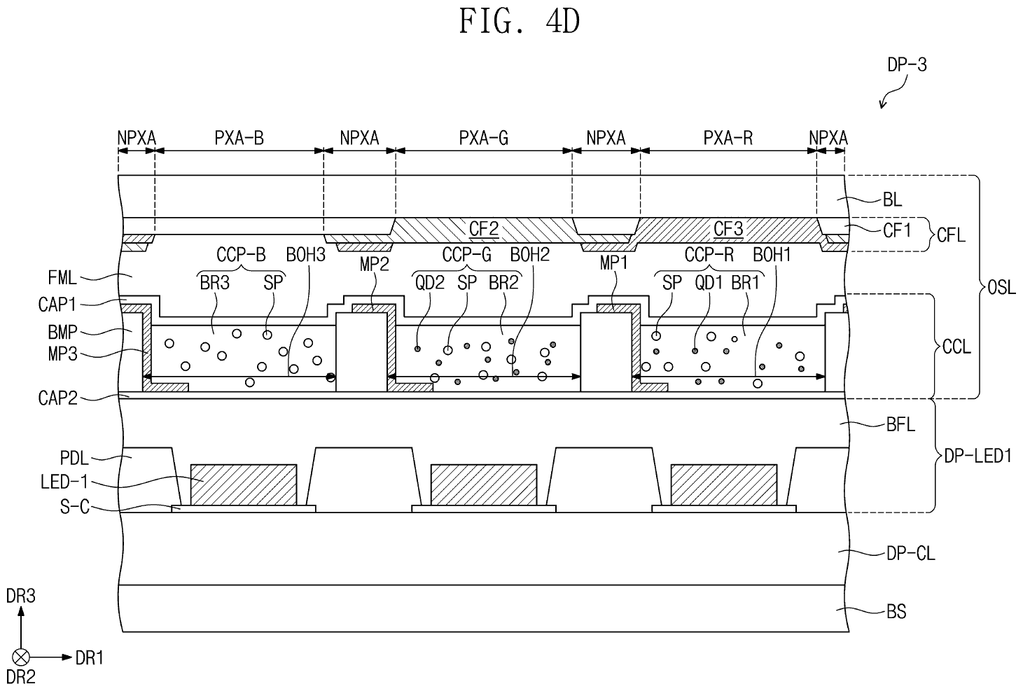

FIG. 2A is an enlarged schematic plan view of a portion of a display panel according to an embodiment. FIG. 2B is an enlarged schematic plan view of a display panel corresponding to area AA illustrated in FIG. 2A according to an embodiment. FIG. 3 is a schematic cross-sectional view of a portion of a display panel according to an embodiment. FIG. 4A is a schematic cross-sectional view of a portion of a display panel according to an embodiment. FIG. 3 illustrates a cross-section taken along line I-I′ illustrated in FIG. 2A. FIG. 4A illustrates a cross-section taken along line II-II′ illustrated in FIG. 2A.

FIGS. 2A and 2B each illustrate an arrangement of multiple pixel areas disposed in the display area DA of the display panel DP (see FIG. 1A) according to an embodiment. In an embodiment, pixel areas PXA-R, PXA-G and PXA-B illustrated in FIG. 2A may be repeatedly arranged throughout the entire display arca DA (see FIG. 1A).

Referring to FIGS. 2A and 2B, a non-light emitting area NPXA may be disposed around first to third pixel areas PXA-R, PXA-G and PXA-B. The non-light emitting area NPXA may define a boundary of the first to third pixel areas PXA-R, PXA-G and PXA-B. The non-light emitting area NPXA may surround the first to third pixel areas PXA-R, PXA-G and PXA-B. In the disclosure, a first pixel area PXA-R, a second pixel area PXA-G, and a third pixel area PXA-B, which are arranged in parallel along a direction (e.g., the first direction DR1), may be set as a group, and this group may be referred to as a “pixel unit PXA-U”.

In the non-light emitting area NPXA, a structure for preventing color mixture between the first to third pixel areas PXA-R, PXA-B, and PXA-G, for example, a pixel defining film PDL (see FIG. 3), a bank BMP (see FIG. 3), or the like may be disposed. At least two color filters to be described later may be disposed to overlap the non-light emitting area NPXA.

As illustrated in FIG. 2A, each of the first to third pixel areas PXA-R, PXA-B, and PXA-G may have a rectangular shape. Each of the first to third pixel areas PXA-R, PXA-B, and PXA-G may have a rectangular shape having short sides extending in the first direction DR1 and long sides extending in the second direction DR2. The first to third pixel areas PXA-R, PXA-B, and PXA-G may be spaced apart from each other in the first direction DR1.

FIG. 2A illustrates the first to third pixel areas PXA-R, PXA-G, and PXA-B each having a rectangular shape, but an embodiment is not limited thereto. Some of the first to third pixel areas PXA-R, PXA-G, and PXA-B may have different shapes, such as polygonal shapes (including a substantially polygonal shape). In an embodiment, each of the first to third pixel areas PXA-R, PXA-G, and PXA-B may have a rectangular shape with rounded corners (e.g., a substantially rectangular shape).

The first pixel area PXA-R, the second pixel area PXA-G, and the third pixel area PXA-B may display light having different wavelengths from each other. One of the first to third pixel areas PXA-R, PXA-G, and PXA-B may provide blue light, another may provide red light, and another may provide green light. In this embodiment, the first pixel area PXA-R may provide red light, the second pixel area PXA-G may provide green light, and the third pixel area PXA-B may provide blue light. The first pixel area PXA-R may emit light having an emission wavelength of about 620 nm to about 700 nm, the second pixel area PXA-G may emit light having an emission wavelength of about 520 nm to about 600 nm, and the third pixel area PXA-SD-241208-ROD 11 B may emit light having an emission wavelength of about 410 nm to about 480 nm.

Although the first to third pixel areas PXA-R, PXA-G, and PXA-B illustrated in FIG. 2A may have the same surface area, an embodiment is not limited thereto, and the respective surface areas of the first to third pixel areas PXA-G, and PXA-B may be adjusted based on emissive colors. A pixel area which emits light having a red color, one of primary colors, may have the largest surface area, and a pixel area which emits light having a blue color may have the smallest surface area. For example, the first pixel area PXA-R which emits red light may have the largest surface area, and the third pixel area PXA-B which emits blue light may have the smallest surface area.

In the display area DA according to an embodiment, a bank opening portion BOH corresponding to each of the pixel areas PXA may be provided. The bank opening portions BOH may be provided for the respective pixel areas PXA so that multiple light control patterns CCP-R, CCP-G, and CCP-B (see FIG. 4A) to be described later are disposed in the corresponding bank opening portions BOH.

The bank opening portions BOH may include a first bank opening portion BOH1 corresponding to the first pixel area PXA-R, a second bank opening portion BOH2 corresponding to the second pixel area PXA-G, and a third bank opening portion BOH3 corresponding to the third pixel area PXA-B. Each of the first to third bank opening portions BOH1, BOH2, and BOH3 may have a rectangular shape. Each of the first to third bank opening portions BOH1, BOH2, and BOH3 may have a rectangular shape having short sides extending in the first direction DR1 and long sides extending in the second direction DR2. The first to third bank opening portions BOH1, BOH2, and BOH3 may be spaced apart from each other in the first direction DR1.

Although not illustrated, a bank well arca may be defined in the display area DA. The bank well area may be an area in which a bank well is formed to prevent defects due to ink application errors in a process of printing some of the light control patterns CCP-R, CCP-G, and CCP-B (see FIG. 4A) included in a light control layer CCL (see FIG. 4A). For example, the bank well area may be an area in which the bank well is defined by removing a portion of a bank BMP (see FIG. 4).

Referring to FIG. 3, a display panel DP according to an embodiment may include a base substrate BS, a circuit element layer DP-CL disposed on the base substrate BS, and a display element layer DP-LED disposed on the circuit element layer DP-CL. In the disclosure, the base substrate BS, the circuit element layer DP-CL, and the display element layer DP-LED may be collectively referred to as a lower panel.

The base substrate BS may be a member that provides a reference surface on which a component included in the circuit element layer DP-CL is disposed. In an embodiment, the base substrate BS may be a glass substrate, a metal substrate, a polymer substrate, or the like. However, an embodiment is not limited thereto, and the base substrate BS may be an inorganic layer, a functional layer, or a composite material layer.

The base substrate BS may have a multilayer structure. For example, the base substrate BS may have a three-layer structure including a polymer resin layer, an adhesive layer, and another polymer resin layer. For example, the polymer resin layer may include a polyimide-based resin. The polymer resin layer may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, or a perylene-based resin. The term “α-based” resin used herein indicates a resin including a functional group “α”.

The circuit element layer DP-CL may be disposed on the base substrate BS. The circuit element layer DP-CL may include a transistor T-D as a circuit element. The configuration of the circuit element layer DP-CL may vary based on the design of a driving circuit of the pixel PX (see FIG. 1A), and one transistor T-D is illustrated as an example in FIG. 3. An arrangement of an active region A-D, a source S-D, a drain D-D, and a G-D gate that constitute the transistor T-D is illustrated as an example. The active region A-D, the source S-D, and the drain D-D may correspond to areas differentiated based on the doping concentration or conductivity of a semiconductor pattern.

The circuit element layer DP-CL may include a lower buffer layer BRL, a first insulation layer 10, a second insulation layer 20, and a third insulation layer 30, which are disposed on the base substrate BS. For example, the lower buffer layer BRL, the first insulation layer 10, and the second insulation layer 20 may be inorganic layers, and the third insulation layer 30 may be an organic layer.

The display element layer DP-LED may include a light emitting element LED as a display element. The light emitting element LED may generate source light. In an embodiment, the source light may be white light or blue light. In an embodiment, the display element layer DP-LED may include an organic light emitting diode as a light emitting element. For example, a light emitting layer EML in the light emitting element LED may include an organic light emitting material.

The light emitting element LED may include a first electrode EL1, a second electrode EL2, and the light emitting layer EML disposed between the first electrode EL1 and the second electrode EL2. In this embodiment, the display element layer DP-LED may include an organic light emitting diode as a light emitting element. In an embodiment, the light emitting element may include a quantum-dot light emitting diode. For example, the light emitting layer EML in the light emitting element LED may include an organic light emitting material as a light emitting material, or the light emitting layer EML may include a quantum dot as a light emitting material. In other embodiments, the display element layer DP-LED may include a subminiature light emitting element to be described later as a light emitting element. The subminiature light emitting element may include, for example, a micro LED element and/or a nano LED element, or the like. The subminiature light emitting element may be a light emitting element having a micro-or nano-scale size and may include an active layer disposed between multiple semiconductor layers.

The first electrode EL1 may be disposed of the third insulation layer 30. The first electrode EL1 may be directly or indirectly connected to the transistor T-D, although a connecting structure between the first electrode EL1 and the transistor T-D is not illustrated in FIG. 3.

The display element layer DP-LED may include a pixel defining layer PDL. For example, the pixel defining layer PDL may be an organic layer. A light emitting opening portion OH may be defined in the pixel defining layer PDL. The light emitting opening portion OH of the pixel defining layer PDL may expose at least a portion of the first electrode EL1. In this embodiment, a first light emitting area EA1 may be defined by the light emitting opening portion OH.

A hole control layer HTR, the light emitting layer EML, and an electron control layer ETR may overlap at least a pixel area PXA-R. Each of the hole control layer HTR, the light emitting layer EML, the electron control layer ETR, and the second electrode EL2 may be disposed, in common, across the first to third pixel areas PXA-R, PXA-G, and PXA-B (refer to FIG. 4A). Each of the hole control layer HTR, the light emitting layer EML, the electron control layer ETR, and the second electrode EL2, which overlap the first to third pixel areas PXA-R, PXA-G, and PXA-B (refer to FIG. 4A), may have a shape of one body. However, an embodiment is not limited thereto, and at least one of the hole control layer HTR, the light emitting layer EML, or the electron control layer ETR may be separately provided for each of the first to third pixel areas PXA-R, PXA-G, and PXA-B (refer to FIG. 4A). In an embodiment, the light emitting layer EML may be patterned within the light emitting opening portion OH and separately provided for each of the first to third pixel areas PXA-R, PXA-G, and PXA-B (refer to FIG. 4A).

The hole control layer HTR may include a hole transport layer and may further include a hole injection layer.

The light emitting EML may generate third light. In an embodiment, the light emitting layer EML may generate blue light. The blue light may include light having a wavelength of about 410 nm to about 480 nm. An emission spectrum of the blue light may have a maximum peak in a wavelength range of about 440 nm to about 460 nm.

The electron control layer ETR may include an electron transport layer and may further include an electron injection layer.

The display element layer DP-LED may include a thin-film encapsulation layer TFE that protects the second electrode EL2. The thin-film encapsulation layer TFE may include an organic material or an inorganic material. The thin-film encapsulation layer TFE may have a multilayer structure in which an inorganic layer and an organic layer are alternately stacked. In this embodiment, the thin-film encapsulation layer TFE may include a first inorganic encapsulation layer IOL1, an organic encapsulation layer OL, and a second inorganic encapsulation layer IOL2. The first and second inorganic encapsulation layers IOL1 and IOL2 may protect the light emitting element LED from external moisture, and the organic encapsulation layer OL may prevent a denting defect in the light emitting element LED caused by foreign matter introduced during a manufacture process. Although not illustrated, the display panel DP may further include a refractive index control layer above the thin-film encapsulation layer TFE to improve light extraction efficiency.

As illustrated in FIG. 3, an optical structure layer OSL may be disposed on the thin-film encapsulation layer TFE. The optical structure layer OSL may include a light control layer CCL, a color filter layer CFL, and a base layer BL. In an embodiment, the optical structure OSL may also be referred to as an upper panel.

The light control layer CCL may be disposed on the display element layer DP-LED that includes the light emitting element LED. The light control layer CCL may include a bank BMP, a first light control pattern CCP-R, a first barrier layer CAP1, and a second barrier layer CAP2.

The bank BMP may include a base resin and an additive. The base resin may include various resin compositions generally referred to as binders. The additive may include a coupling agent and/or a photoinitiator. The additive may further include a dispersing agent.

In an embodiment, the bank BMP included in the light control layer CCL may be optically transparent. The bank BMP may include an optically transparent material. The base resin included in the BMP bank may be optically transparent. The bank BMP may include a material having a transmittance of about 85% or more in a visible light range. The bank BMP may not include a separate coloring agent. The bank BMP may not include black dye or black pigment mixed into the base resin. In an embodiment, the bank BMP may not include a light blocking material such as carbon black having a black color, or a dye or pigment having a blue color or the like.

The bank BMP may include a liquid-repellent material. As the bank BMP includes the liquid-repellent material, an overflow phenomenon of an ink composition provided in each of the bank opening portions BOH1, BOH2, and BOH3 may be prevented. In a case in which the light control patterns CCP-R, CCP-G, and CCP-B are formed through a printing method such as inkjet process, the provided ink composition may be in contact with a surface of the bank BMP including the liquid-repellent material, thereby preventing an overflow phenomenon of the light control patterns CCP-R, CCP-G and CCP-B. For example, the ink composition may not diffuse upward from the bank BMP but be disposed only in a space inside each of the bank opening portions BOH1, BOH2, and BOH3. The ink composition may be disposed only in the spaces inside the bank opening portions BOH1, BOH2, and BOH3 without diffusing upward from the bank BMP or color-mixing with a neighboring ink composition.

The bank BMP may include the bank opening portion BOH1 corresponding to the light emitting opening portion OH. In a plan view, the bank opening portion BOH1 may overlap the light emitting opening portion OH and may have a larger surface area than the light emitting opening portion OH. For example, the bank opening portion BOH1 may have a larger surface area than the light emitting area EA1 defined by the light emitting opening portion OH. In the disclosure, two components described as “corresponding” to each other means that the two components overlap each other when viewed in the thickness direction of the display panel DP and does not necessarily imply that the two components have the same surface area.

The first light control pattern CCP-R may be disposed inside the bank opening portion BOH1. The first light control pattern CCP-R may change or modify optical properties of the source light.

The first light control pattern CCP-R may include a first quantum dot QD1 for changing the optical properties of the source light. The first light control pattern CCP-R may include the first quantum dot QD1 that converts the source light to light having a different wavelength. In the first light control pattern CCP-R overlapping the second pixel area PXA-G, the first quantum dot QD1 may convert the source light to red light.

In the disclosure, the “quantum dot” may refer to a crystal of a semiconductor compound. The quantum dot may emit light having various emission wavelengths depending on the size of the crystal. The quantum dot may also emit light having various emission wavelengths by adjusting a ratio of elements in the quantum dot compound.

A diameter of the quantum dot may be, for example, about 1 nm to about 10 nm.

The quantum dot may be synthesized through a wet chemical process, a metal-organic chemical vapor deposition (MOCVD) process, a molecular beam epitaxy (MBE) process, or the like.

The wet chemical process may involve a method of mixing an organic solvent and a precursor material and growing quantum dot particle crystals. During crystal growth, the organic solvent may act as a dispersant that naturally coordinates with surfaces of the quantum dot crystals and controls the growth of the crystals. Thus, in the wet chemical process, the growth of quantum dot particles may be controlled through a simpler and more cost-effective process compared to a vapor deposition process such as MOCVD or MBE.

A core of the quantum dot may be selected from a Group II-VI compound, a Group III-V compound, a Group III-VI compound, a Group I-III-VI compound, a Group IV-VI compound, a Group IV element, a Group IV compound, or a combination thereof.

The Group II-VI compound may include a binary compound such as CdSe, CdTe, CdS, ZnS, ZnSe, ZnTe, ZnO, HgS, HgSe, HgTe, MgSe, MgS, or a mixture thereof, a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSc, MgZnS, or a mixture thereof, and a quaternary compound such as HgZnTeS, CdZnSeS, CdZnSeTe, CdZnSTe, CdHgSeS, CdHgSeTe, CdHgSTe, HgZnSeS, HgZnSeTe, or a mixture thereof. A Group II-VI semiconductor compound may further include a Group I metal and/or a Group IV element. The Group I-II-VI compound may be selected from CuSnS or CuZnS, the Group II-IV-VI compound may be selected from ZnSnS or the like. The Group I-II-IV-VI compound may be selected from a quaternary compound including Cu₂ZnSnS₂, Cu₂ZnSnS₄, Cu₂ZnSnSc₄, Ag₂ZnSnS₂, or a mixture thereof.

The Group III-VI compound may include a binary compound such as In₂S₃ or In₂Sc₃, a ternary compound such as InGaS₃ or InGaSe₃, or any combination thereof.

The Group I-III-VI compound may include a ternary compound such as AgInS, AgInS₂, CuInS, CuInS₂, AgGaS₂, CuGaS₂ CuGaO₂, AgGaO₂, AgAlO₂, or a mixture thereof, or a quaternary compound such as AgInGaS₂ or CuInGaS₂.

The Group III-V compound may include a binary compound such as GaN, GaP, GaAs, GaSb, AlN, AlP, AlAs, AlSb, InN, InP, InAs, InSb, or a mixture thereof, a ternary compound such as GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, or a mixture thereof, and a quaternary compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, or a mixture thereof. The Group III-V compound may further include a Group II metal. For example, InZnP or the like may be selected as a Group III-II-V compound.

The Group IV-VI compound may include a binary compound such as SnS, SnSe, SnTe, PbS, PbSe, PbTe, or a mixture thereof, a ternary compound such as SnSeS, SnSeTe, SnSTe, PbSeS, PbSeTe, PbSTe, SnPbS, SnPbSe, SnPbTe, or a mixture thereof, and a quaternary compound such as SnPbSSe, SnPbSeTe, SnPbSTe, or a mixture thereof.

Examples of the Group II-IV-V compound may include a ternary compound such as ZnSnP, ZnSnP₂, ZnSnAs₂, ZnGcP₂, ZnGeAs₂, CdSnP₂, or CdGeP₂, or a mixture thereof.

The Group IV element may include Si, Ge, or a mixture thereof. The Group IV compound may be a binary compound including SiC, SiGe, or a mixture thereof.

Each of elements included in a multi-element compound such as the binary compound, the ternary compound and the quaternary compound, may be present in a particle at either a uniform concentration or non-uniform concentration. In an embodiment, the foregoing formulas may indicate types of elements included in the compound, but ratios of these elements in the compound may vary. For example, AgInGaS₂ may indicate AgInₓGa₁₋ₓS₂ (where x is a real number between 0 and 1).

The binary compounds, the ternary compounds, or the quaternary compounds may be uniformly distributed in a particle, or may be present in the same particle with regions having partially different concentration distributions. The quantum dot may have a core-shell structure in which one quantum dot surrounds another quantum dot. In the core-shell structure, the quantum dot may have a concentration gradient in which the concentration of an element present in the shell gradually decreases toward the core.

In some embodiments, the quantum dot may have a core-shell structure that includes a core having the aforementioned nanocrystal and a shell surrounding the core. The shell of the quantum dot may serve as a protective layer to prevent chemical modification of the core and maintain semiconductor characteristics, and/or serve as a charging layer to impart electrophoretic properties to the quantum dot. The shell may have a single-layer structure or a multilayer structure. The shell of the quantum dot may be, for example, a metal or nonmetal oxide, a semiconductor compound, or a combination thereof.

For example, the metal or nonmetal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and NiO, or a ternary compound such as MgAl₂O₄, CoFe₂O₄, NiFe₂O₄, and CoMn₂O₄, but an embodiment is not limited thereto.

Examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, AlAs, AlP, and AlSb, but an embodiment is not limited thereto.

The quantum dot may have a full width at half maximum (FWHM) of an emission wavelength spectrum of about 45 nm or less, for example, about 40 nm or less, for example, about 30 nm or less. In this range, color purity or color reproducibility may be improved. Moreover, light emitted through such quantum dots may be emitted in all directions, thereby improving the viewing angle of the emitted light.

The shape of the quantum dot may be a form commonly used in the art, and is not particularly limited. For example, the quantum dot may have a spherical, pyramidal, or multi-armed form, or may take the form of cubic nanoparticles, nanotubes, nanowires, nanofibers, nanoplate particles, or the like.

In the quantum dot, an energy band gap may be adjusted by changing the size of the quantum dot or by adjusting the ratio of elements in a quantum dot compound, and thus light having various wavelength bands may be obtained in the quantum dot light emitting layer. Thus, a light emitting element that emits light having multiple wavelengths may be achieved by using the quantum dots (having different sizes or having different ratios of elements in a quantum dot compound) as described above. For example, the size of the quantum dot or the ratio of elements in the quantum dot compound may be selectively adjusted to emit red, green, and/or blue light. The quantum dots may emit white light by combining light of various colors.

In an embodiment, the first quantum dot QD1 included in the first light control pattern CCP-R overlapping the first pixel area PXA-R may have a red emissive color. As the particle size of the quantum dot decreases, the quantum dot may emit light having a shorter wavelength range. For example, in the quantum dots having the same core, a particle size of the quantum dot emitting green light may be shorter than a particle size of the quantum dot emitting red light. In the quantum dots having the same core, a particle size of the quantum dot emitting blue light may be smaller than the particle size of the quantum dot emitting green light. However, an embodiment is not limited thereto, and, even in the quantum dots having the same core, the particle sizes may be adjusted based on a material forming the shell, a shell thickness, or the like.

In a case in which quantum dots have various emissive colors such as blue, red, and green, the quantum dots having different emissive colors may be different from each other in terms of their core materials.

The first light control pattern CCP-R may further include a scattered SP. The first light control pattern CCP-R may include the first quantum dot QD1, which converts blue light to red light, and the scatterer SP, that scatters light.

The scatterer SP may be an inorganic particle. For example, the scatterer SP may include at least one of TiO₂, ZnO, Al₂O₃, SiO₂, or hollow silica. The scatterer SP may include any of TiO₂, ZnO, Al₂O₃, SiO₂, or hollow silica, or maybe a mixture of two or more materials selected from TiO₂, ZnO, Al₂O₃, SiO₂, or hollow silica.

The first light control pattern CCP-R may include a first base resin BR1 which disperses the first quantum dot QD1 and the scatterer SP. The first base resin BR1, which is a medium in which the first quantum dot QD1 and the scatterer SP are dispersed, may include various resin compositions generally referred to as binders. For example, the first base resin BR1 may be an acryl-based resin, a urethane-based resin, a silicon-based resin, an epoxy-based resin, or the like. The first base resin BR1 may be a transparent resin. The first base resin BR1 may be a resin selected to perform an inkjet process.

In this embodiment, the first light control pattern CCP-R may be formed through the inkjet process. A liquid composition may be provided in the first bank opening portion BOH1, and undergo a curing process to form the first light control pattern CCP-R. The composition that is polymerized by a thermal curing process or a light curing process may be reduced in volume after curing.

The light control layer CCL may include a first barrier layer CAP1 disposed on a surface of the first light control pattern CCP-R. The first barrier layer CAP1 may prevent permeation of moisture and/or oxygen (hereinafter referred to as “moisture/oxygen”) and may adjust a refractive index to improve optical characteristics of the optical structure layer OSL. The first barrier layer CAP1 may be disposed on an upper surface or a lower surface of the first light control pattern CCP-R, thereby preventing the first light control pattern CCP-R from being exposed from moisture/oxygen, and for example, preventing the quantum dot included in the first light control pattern CCP-R from being exposed to moisture/oxygen. The first barrier layer CAP1 may also protect the first light control pattern CCP-R from an external impact.

In an embodiment, the first barrier layer CAP1 may be disposed apart from the display element layer DP-LED, with the first light control pattern CCP-R positioned therebetween. The first barrier layer CAP1 may be disposed on a top surface (or upper surface) of the first light control pattern CCP-R. In an embodiment, the light control layer CCL may include a second barrier layer CAP2 disposed between the first light control pattern CCP-R and the display element layer DP-LED. The first barrier layer CAP1 may cover the top surface of the first light control pattern CCP-R adjacent to the color filter layer CFL, and the second barrier layer CAP2 may cover the bottom surface of the first light control pattern CCP-R adjacent to the display element layer DP-LED. In the disclosure, the term “top surface” or “upper surface” may refer to a surface placed on an upper side based on the third direction DR3, and the term “bottom surface” or “lower surface” may refer to a surface placed on a lower side based on the third direction DR3.

Each of the first barrier layer CAP1 and the second barrier layer CAP2 may cover a surface of the bank BMP in addition to covering a surface of the first light control pattern CCP-R.

The first barrier layer CAP1 may cover a surface of each of the bank BMP and the first light control pattern CCP-R, which is adjacent to the color filter layer CFL. The first barrier layer CAP1 may be disposed (or directly disposed) below a filling layer FML. The second barrier layer CAP2 may be disposed (or directly disposed) on the thin-film encapsulation layer TFE. The light control layer CCL may be disposed on the display element layer DP-LED and the thin-film encapsulation layer TFE, with the second barrier layer CAP2 positioned therebetween. The light control patterns CCP-R, CCP-G, and CCP-B (see FIG. 4A) of the light control layer CCL may be formed through a continuous process on the second barrier layer CAP2 disposed on the thin-film encapsulation layer TFE.

The first barrier layer CAP1 and the second barrier layer CAP2 may each include an inorganic material. In an embodiment of the display panel DP, the first barrier layer CAP1 may include silicon oxynitride (SiOₓN_{y}). Both the first barrier layer CAP1 and the second barrier layer CAP2 may include silicon oxynitride (SiOₓN_{y}). However, an embodiment is not limited thereto, and each of the first barrier layer CAP1 and the second barrier layer CAP2 may include silicon oxide (SiOₓ) or silicon nitride (SiNₓ). In an embodiment, the first barrier layer CAP1 disposed on the first light control pattern CCP-R may include silicon oxynitride, and the second barrier layer CAP2 below the first light control pattern CCP-R may include silicon oxide.

The color filter layer CFL may be disposed on the light control layer CCL. The color filter layer CFL may include at least one color filter. The color filter may transmit light having a specific wavelength range and block light having a wavelength range outside of the specific wavelength range. A first color filter CF1 corresponding to the first pixel area PXA-R may transmit red light and block green light and blue light.

The first color filter CF1 may include a base resin and a pigment and/or a dye dispersed in the base resin. The base resin may serve as a medium for dispersing a pigment and/or a dye and may include various resin compositions commonly referred to as binders.

The first color filter CF1 may have a uniform thickness in the first pixel area PXA-R. Red light, converted from the source light (blue light) through the first light control pattern CCP-R may be emitted to the outside with uniform luminance in the first pixel area PXA-R.

The optical structure layer OSL may further include a filling layer FML disposed between the light control layer CCL and the color filter layer CFL. In an embodiment, the filling layer FML may fill a space between the light control layer CCL and the color filter layer CFL. The filling layer FML may be disposed (or directly disposed) on the first barrier layer CAP1, and the color filter layer CFL may be disposed (or directly disposed) on the filling layer FML. A bottom surface (or lower surface) of the filling layer FML may be in contact with the top surface of the first barrier layer CAP1, and a top surface (or upper surface) of the filling layer FML may be in contact with bottom surfaces of the color filters CF1, CF2, and CF3 of the color filter layer CFL.

The filling layer FML may function as a buffer between the light control layer CCL and the color filter layer CFL. In an embodiment, the filling layer FML may perform a shock absorbing function or the like and may enhance the strength of the display panel DP. The filling layer FML may be formed from a filling resin including a polymer resin. For example, the filling layer FML may be formed from a filling resin including an acryl-based resin, an epoxy-based resin, or the like.

The filling layer FML may be disposed between the light control layer CCL and the color filter layer CFL and may function as an optical functional layer that, for example, increases light extraction efficiency or prevents reflected light from entering the light control layer CCL. The filling layer FML may be a layer having a lower refractive index than the adjacent layers.

In an embodiment, the display panel DP may further include a base layer BL disposed on the color filter layer CFL. The base layer BL may be a member that provides a reference surface on which the color filter layer CFL, the light control layer CCL, and the like are disposed. The base layer BL may be a glass substrate, a metal substrate, a plastic substrate, or the like. However, an embodiment is not limited thereto, and the base layer BL may be an inorganic layer, an organic layer, or a composite material layer. In another embodiment, the base layer BL may be omitted.

Although not illustrated, an anti-reflective layer may be disposed on the base layer BL. The anti-reflective layer may be a layer that reduces the reflectance of external light incident from outside the display panel DP. The anti-reflective layer may be a layer that selectively transmits light emitted from the display panel DP. In an embodiment, the anti-reflective layer may be a single layer including a dye and/or pigment dispersed in a base resin. The anti-reflective layer may be provided as a continuous layer that entirely overlaps the first to third pixel areas PXA-R, PXA-G, and PXA-B (see FIG. 4A).

The anti-reflective layer may not include a polarizing layer. Accordingly, light passing through the anti-reflective layer and incident on a side of the display element layer DP-LED may be non-polarized light. The display element layer DP-LED may receive non-polarized light from above the anti-reflective layer.

Referring to FIG. 4A, a display module DP may include a base substrate BS and a circuit element layer DP-CL disposed on the base substrate BS. The circuit element layer DP-CL may be disposed on the base substrate BS. The circuit element layer DP-CL may include an insulation layer, a semiconductor pattern, a conductive pattern, a signal line, and the like. The insulation layer, a semiconductor layer, and a conductive layer may be formed on the base substrate BS through coating, deposition or the like, and the insulation layer, the semiconductor layer, and the conductive layer may be selectively patterned by performing a photolithography process multiple times. The semiconductor pattern, the conductive pattern, and the signal line which are included in the circuit element layer DP-CL may be formed. In an embodiment, the circuit element layer DP-CL may include a transistor, a buffer layer, and multiple insulation layers.

A light emitting element LED according to an embodiment may include a first electrode EL1, a second electrode EL2 facing the first electrode EL1, and a light emitting layer EML disposed between the first electrode EL1 and the second electrode EL2. The light emitting layer EML included in the light emitting element LED may include an organic light emitting material or a quantum dot as a light emitting material. The light emitting element LED may further include a hole control layer HTR and an electron control layer ETR. Although not illustrated, the light emitting element LED may further include a capping layer (not illustrated) disposed on the second electrode EL2.

A pixel defining layer PDL may be disposed on the circuit element layer DP-CL and may cover a portion of the first electrode EL1. A light emitting opening portion OH may be defined in the pixel defining layer PDL. The light emitting opening portion OH of the pixel defining layer PDL may expose at least a portion of the first electrode EL1. In this embodiment, each of light emitting areas EA1, EA2, and EA3 may correspond to a partial area of the first electrode EL1, which is exposed by the light emitting opening portion OH.

A circuit element layer DP-CL may include a first light emitting area EA1, a second light emitting area EA2, and a third light emitting area EA3. The first light emitting area EA1, the second light emitting area EA2, and the third light emitting area EA3 may be areas divided by the pixel defining layer PDL. The first light emitting area EA1, the second light emitting area EA2, and the third light emitting area EA3 may correspond to a first pixel areas PXA-R, a second pixel arca PXA-G, and a third pixel area PXA-B, respectively.

The light emitting areas EA1, EA2, and EA3 may overlap the pixel areas PXA-R, PXA-G, and PXA-B, respectively. In a plan view, surface areas of the pixel areas PXA-R, PXA-G, and PXA-B, divided by color filters CF1, CF2, and CF3, may be substantially the same as surface areas of the light emitting areas EA1, EA2, and EA3, divided by the pixel defining layer PDL, respectively.

In the light emitting element LED, the first electrode EL1 may be disposed on the circuit element layer DP-CL. The first electrode EL1 may function as an anode or a cathode. The first electrode EL1 may also be a pixel electrode. The first electrode EL1 may be a transmissive electrode, a semi-transmissive electrode, or a reflective electrode.

The hole control layer HTR may be disposed between the first electrode EL1 and the light emitting layer EML. The hole control layer HTR may include at least one of a hole injection layer, a hole transport layer, or an electron blocking layer. The hole control layer HTR may be disposed as a common layer that overlaps the entirety of the light emitting areas EA1, EA2, and EA3 and the pixel defining film PDL which divides the light emitting areas EA1, EA2, and EA3. However, an embodiment is not limited thereto, and the hole control layer HTR may be patterned and separately disposed to correspond to each of the light emitting areas EA1, EA2, and EA3.

The light emitting layer EML may be disposed on the hole control layer HTR. In an embodiment, the light emitting layer EML may be disposed as a common layer that overlaps the entirety of the light emitting areas EA1, EA2, and EA3 and the pixel defining film PDL which divides the light emitting areas EA1, EA2, and EA3. In an embodiment, the light emitting layer EML may emit blue light. The light emitting layer EML may overlap the entirety of the hole control layer HTR and the electron control layer ETR.

However, an embodiment is not limited thereto, and in an embodiment, the light emitting layer EML may be disposed within a light emitting opening portion OH. For example, the light emitting layer EML may be separately provided to correspond to each of the light emitting areas EA1, EA2, and EA3 divided by the pixel defining layer PDL. The light emitting layers EML, separated to correspond the light emitting areas EA1, EA2, and EA3, may all emit blue light, or may emit light having different wavelength regions.

The light emitting layer EML may have a single layer made of a single material, or a single layer made of multiple different materials, or a multilayer structure having multiple layers made of different materials. The light emitting layer EML may include a fluorescent material or a phosphorescent material. In a light emitting element according to an embodiment, the light emitting layer EML may include a light emitting material such as an organic light emitting material, an organometallic complex, or a quantum dot. As an example, FIGS. 3 and 4A illustrate a light emitting element LED including a light emitting layer EML, but in some embodiments, the light emitting element LED may include multiple light emitting stacks, each including at least one light emitting layer.

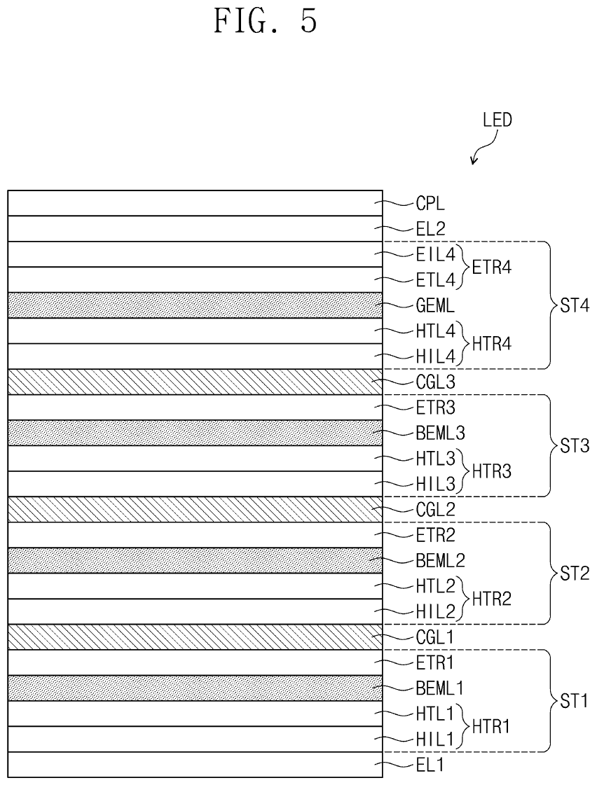

FIG. 5 is a schematic cross-sectional view of a light emitting element according to an embodiment. As an example, FIG. 5 illustrates a light emitting element LED including multiple light emitting stacks ST1, ST2, ST3, and ST4, unlike the light emitting elements illustrated in FIGS. 3 and 4A.

Referring to FIG. 5, the light emitting element LED according to an embodiment may include a first electrode EL1, a second electrode EL2 facing the first electrode EL1, and first to fourth light emitting stacks ST1, ST2, ST3, and ST4 disposed between the first electrode EL1 and the second electrode EL2. As an example, FIG. 5 illustrates the light emitting element LED including four light emitting stacks, but the number of the light emitting stacks included in the light emitting element LED may be fewer than four or greater than four.

The light emitting element LED may include first to third charge generation layers CGL1, CGL2, and CGL3 disposed, respectively, in spaces between the first to fourth light emitting stacks ST1, ST2, ST3, and ST4.

In a case where a voltage is applied, each of the first to third charge generation layers CGL1, CGL2, and CGL3 may generate charges (electrons and holes) by forming a complex through an oxidation-reduction reaction. Each of the first to third charge generation layers CGL1, CGL2, and CGL3 may provide generated charges to adjacent stacks ST1, ST2, ST3, and ST4. The first to third charge generation layers CGL1, CGL2, and CGL3 may enhance the efficiency of the current generated from the adjacent stacks ST1, ST2, ST3, and ST4 and may function to balance the charges between the adjacent stacks ST1, ST2, ST3, and ST4.

Each of the first to third charge generation layers CGL1, CGL2, and CGL3 may include an n-type layer and a p-type layer. The first to third charge generation layers CGL1, CGL2, and CGL3 may have a structure in which the n-type layer and the p-type layer are bonded to each other. However, an embodiment is not limited thereto, and the first to third charge generation layers CGL1, CGL2, and CGL3 may include only an n-type layer or only a p-type layer. The n-type layer may be a charge generation layer that provides electrons to an adjacent stack. The n-type layer may be a layer in which a base material is doped with an n-dopant. The p-type layer may be a charge generation layer that provides holes to an adjacent stack.

In an embodiment, each of the first to third generation layers CGL1, CGL2, and CGL3 may have a thickness of about 1 angstrom (Å) to about 150 angstrom (Å). The n-dopant doped in the first to third charge generation layers CGL1, CGL2, and CGL3 may have a concentration of about 0.1% to about 3%, and for example, about 1% or less. In a case in which the concentration is less than about 0.1%, the charge balance adjustment effects of the first to third charge generation layers CGL1, CGL2, and CGL3 may be minimal. In a case in which the concentration exceeds about 3%, the light efficiency of the light emitting element LED may decrease.

Each of the first to third charge generation layers CGL1, CGL2, and CGL3 may include a charge generation compound that includes an aryl amine-based organic compound, a metal, a metal oxide, carbide, or fluoride, or a mixture thereof. For example, the aryl amine-based organic compound may include α-NPD, 2-TNATA, TDATA, MTDATA, sprio-TAD, or sprio-NPB. The metal may include cesium (Cs), molybdenum (Mo), vanadium (V), titanium (Ti), tungsten (W), barium (Ba), or lithium (Li). The metal oxide, carbide, or fluoride may include Re₂O₇, MoO₃, V₂O₅, WO₃, TiO₂, Cs₂CO₃, BaF, LiF, or CsF. However, the materials used for the first to third charge generation layers CGL1, CGL2, and CGL3 are not limited to the foregoing examples.

Each of the first to fourth light emitting stacks ST1, ST2, ST3, and ST4 may include a light emitting layer. The first light emitting stack ST1 may include a first light emitting layer BEML1, the second light emitting stack ST2 may include a second light emitting layer BEML2, the third light emitting stack ST3 may include a third light emitting layer BEML3, and the fourth light emitting stack ST4 may include a fourth light emitting layer GEML. Some of the light emitting layers included in the first to fourth light emitting stacks ST1, ST2, ST3, and ST4 may emit light of substantially the same color, and others may emit light of different colors.

In an embodiment, the first to third light emitting layers BEML1, BEML2, and BEML3 of the first to third light emitting stacks ST1, ST2, and ST3 may emit light having substantially the same first color. For example, the light having the first color may be blue light that corresponds to the above-described source light. The light emitted by the first to third light emitting layers BEML1, BEML2, and BEML3 may have a wavelength range of about 420 nm to about 480 nm.

The fourth light emitting layer GEML of the fourth light emitting stack ST4 may emit light having a second color different from the first color. For example, the second color may be green light. The light emitted by the fourth light emitting layer GEML may have a wavelength range of about 520 nm to about 600 nm.

The light emitting element LED may emit light in a direction from the first electrode EL1 to the second electrode EL2. In the light emitting element LED according to an embodiment, the stacks ST1, ST2, ST3, and ST4 may include hole transport regions HTR1, HTR2, HTR3, and HTR4 and electron transport regions ETR1, ETR2, ETR3, and ETR4, respectively. The hole transport regions HTR1, HTR2, HTR3, and HTR4 may transport holes provided from the first electrode EL1 or the charge generation layers CGL1, CGL2, and CGL3 to the light emitting layers. The electron transport regions ETR1, ETR2, ETR3, and ETR4 may transport electrons provided from the second electrode EL2 or the charge generation layers CGL1, CGL2, and CGL3 to the light emitting layers.

As an example, the light emitting element LED according to an embodiment is illustrated as having a structure in which, based on the direction of light emission, the hole transport regions HTR1, HTR2, HTR3, and HTR4 may be disposed below the light emitting layers BEML1, BEML2, BEML3, and GEML included in the stacks ST1, ST2, ST3, and ST4, respectively, and the electron transport regions ETR1, ETR2, ETR3, and ETR4 may be disposed above the light emitting layers BEML1, BEML2, BEML3, and GEML included in the stacks ST1, ST2, ST3, and ST4, respectively. The light emitting element LED according to an embodiment may have a forward device structure. However, an embodiment is not limited thereto, and the light emitting element LED according to an embodiment may have an inverted device structure in which, based on the direction of light emission, the electron transport regions ETR1, ETR2, ETR3, and ETR4 may be disposed below the light emitting layers BEML1, BEML2, BEML3, and GEML included in the stacks ST1, ST2, ST3, and ST4, respectively, and the hole transport regions HTR1, HTR2, HTR3, and HTR4 may be disposed above the light emitting layers BEML1, BEML2, BEML3, and GEML included in the stacks ST1, ST2, ST3, and ST4, respectively.

The hole transport regions HTR1, HTR2, HTR3, and HTR4 may include hole injection layers HIL1, HIL2, HIL3, and HIL4 and hole transport layers HTL1, HTL2, HTL3, and HTL4 disposed on the hole injection layers HIL1, HIL2, HIL3, and HIL4, respectively. Each of the hole transport layers HTL1, HTL2, HTL3, and HTL4 may be in contact with a bottom surface (or lower surface) of the light emitting layer. However, an embodiment is not limited thereto, and the hole transport regions HTR1, HTR2, HTR3, and HTR4 may further include hole side additional layers disposed on the hole transport layers HTL1, HTL2, HTL3, and HTL4, respectively. The hole side additional layers may each include at least one of a hole buffer layer, a light emitting auxiliary layer, or an electron blocking layer. The hole buffer layer may compensate for a resonance distance based on wavelengths of light emitted from a light emitting layer to increase light emission efficiency. The electron blocking layer may function to prevent electrons from being injected from an electron transport region into a hole transport region.

The electron transport regions ETR1, ETR2, ETR3, and ETR4 may each include an electron transport layer. The electron transport regions ETR1, ETR2, ETR3, and ETR4 may each further include an electron injection layer disposed on the electron transport layer. For example, the fourth electron transport region ETR4 included in the fourth light emitting stack ST4 may further include a fourth electron injection layer EIL4 disposed on a fourth electron transport layer ETLA. The electron transport regions ETR1, ETR2, ETR3, and ETR4 may each further include an electron side additional layer disposed between the electron transport layer and the light emitting layers. The electron side additional layer may include at least one of an electron buffer layer or a hole blocking layer.

In the light emitting element LED according to an embodiment, the first electrode EL1 may be a reflective electrode. For example, the first electrode EL1 may include a material with high reflectance, such as Ag, Mg, Cu, Al, Pt, Pd, Au, Ni, Nd, Ir, Cr, Li, Ca, LiF/Ca, LiF/Al, Mo, Ti, W, In, Zn, or Sn, or a compound or mixture thereof (e.g., a mixture of Ag and Mg). In another embodiment, the first electrode EL1 may have a multilayer structure including a reflective film including the foregoing material and a transparent conductive film including indium tin oxide (ITO), indium zinc oxide (IZO), zinc oxide (ZnO), indium tin zinc oxide (ITZO), or the like. For example, the first electrode EL1 may have a two-layer structure of ITO/Ag or a three-layer structure of ITO/Ag/ITO, but is not limited thereto. The first electrode EL1 may include the foregoing metal material, a combination of two or more metal materials selected from the foregoing metal materials, an oxide of the foregoing metal materials, or the like. The first electrode EL1 may have a thickness of about 70 nm to about 1000 nm. For example, the thickness of the first electrode EL1 may be about 100 nm to about 300 nm.

In the light emitting element LED according to an embodiment, each of the hole transport regions HTR1, HTR2, HTR3, and HTR4 may have a single layer made of a single material, or a single layer made of multiple different materials, or a multilayer structure having multiple layers made of different materials.

Each of hole transport regions HTR1, HTR2, HTR3, and HTR4 may be formed using various methods such as vacuum deposition, spin coating, casting, Langmuir-Blodgett (LB), inkjet printing, laser printing, or laser induced thermal imaging (LITI).

The hole transport regions HTR1, HTR2, HTR3, and HTR4 may each include a phthalocyanine compound such as copper phthalocyanine, N¹,N^{1′}-([1,1′-biphenyl]-4,4′-diyl)bis (N¹-phenyl-N⁴,N⁴-di-m-tolylbenzene-1,4-diamine) (DNTPD), 4,4′,4″-[tris(3-methylphenyl)phenylamino] triphenylamine (m-MTDATA), 4,4′4″-Tris(N,N-diphenylamino)triphenylamine (TDATA), 4,4′,4″-tris[N(2-naphthyl)-N-phenylamino]-triphenylamine (2-TNATA), Poly(3,4-ethylenedioxythiophene)/Poly(4-styrenesulfonate) (PEDOT/PSS), (Polyaniline/Dodecylbenzenesulfonic acid (PANI/DBSA), Polyaniline/Camphor sulfonicacid (PANI/CSA), Polyaniline/Poly(4-styrenesulfonate) (PANI/PSS), N,N′-di(naphthalene-1-yl)-N,N′-diphenyl-benzidine (NPB), triphenylamine-containing polyetherketone (TPAPEK), 4-Isopropyl-4′-methyldiphenyliodonium [Tetrakis(pentafluorophenyl)borate], dipyrazino[2,3-f: 2′,3′-h] quinoxaline-2,3,6,7,10,11-hexacarbonitrile (HATCN), or the like.

The hole transport regions HTR1, HTR2, HTR3, and HTR4 may each include a carbazole derivative such as N-phenyl carbazole or polyvinyl carbazole, a fluorene-based derivative, a triphenylamine-based derivative such as N,N′-bis(3-methylphenyl)-N,N′-diphenyl-[1,1′-biphenyl]-4,4′-diamine (TPD) or 4,4′,4″-tris(N-carbazolyl)triphenylamine (TCTA), N,N′-di(naphthalene-1-yl)-N,N′-diphenyl-benzidine (NPB), 4,4′-Cyclohexylidene bis[N,N-bis(4-methylphenyl)benzenamine] (TAPC), 4,4′-Bis[N,N′-(3-tolyl)amino]-3,3′-dimethylbiphenyl (HMTPD), 1,3-Bis (N-carbazolyl) benzene (mCP), or the like.

In another embodiment, the hole transport regions HTR1, HTR2, HTR3, and HTR4 may each include 9-(4-tert-Butylphenyl)-3,6-bis (triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), or the like.

In the hole transport regions HTR1, HTR2, HTR3, and HTR4, the foregoing compounds of the hole transport regions may be included in at least one of the hole injection layers HIL1, HIL2, HIL3, and HIL4, the hole transport layers HTL1, HTL2, HTL3, and HTL4, or the hole side additional layers.

Each of the hole transport regions HTR1, HTR2, HTR3, and HTR4 may have a thickness of about 10 nm to about 1000 nm, for example, about 10 nm to about 500 nm. Each of the hole injection layers HIL1, HIL2, HIL3, and HIL4 may have a thickness of, for example, about 5 nm to about 100 nm. Each of the hole transport layers HTL1, HTL2, HTL3, and HTL4 may have a thickness of about 5 nm to about 100 nm. In a case in which each of the hole transport regions HTR1, HTR2, HTR3, and HTR4 includes a hole side additional layer, the hole side additional layer may have a thickness of about 1 nm to about 100 nm. In a case in which the respective thicknesses of the hole transport regions HTR1, HTR2, HTR3, and HTR4 and their constituent layers fall within the foregoing ranges, satisfactory hole transport characteristics may be obtained without significantly increasing a driving voltage.

Each of the hole transport regions HTR1, HTR2, HTR3, and HTR4 may further include, in addition to the foregoing materials, a charge generation material to improve conductivity. The charge generation material may be uniformly or non-uniformly dispersed in the hole transport regions HTR1, HTR2, HTR3, and HTR4. The charge generation material may be, for example, a p-type dopant. The p-type dopant may include at least one of halogenated metal compounds, quinone derivatives, metal oxides, or cyano group-containing compounds, but is not limited thereto. For example, the p-type dopant may include halogenated metal compounds such as CuI and RbI, quinone derivatives such as Tetracyanoquinodimethane (TCNQ) and 2,3,5,6-tetrafluoro-7,7′8,8-tetracyanoquinodimethane (F4-TCNQ), metal oxides such as tungsten oxides and molybdenum oxides, or the like, but an embodiment is not limited thereto.

Each of the blue light emitting layers BEML1, BEML2, and BEML3 and the green light emitting layer GEML may include a host material and a dopant material. Each of the blue light emitting layers BEML1, BEML2, and BEML3 and the green light emitting layer GEML may include, as a hole transporting host material, a material including a carbazole derivative moiety or an amine derivative moiety. Each of the blue light emitting layers BEML1, BEML2, and BEML3 and the green light emitting layer GEML may include, as an electron transporting host material, a material including a nitrogen-containing aromatic ring structure, such as a pyridine derivative moiety, a pyridazine derivative moiety, a pyrimidine derivative moiety, a pyrazine derivative moiety, or a triazine derivative moiety.

Each of the blue light emitting layers BEML1, BEML2, and BEML3 and the green light emitting layer GEML may include, as a host material, an anthracene derivative, a pyrene derivative, a fluoranthene derivative, a chrysene derivative, a dihydrobenzanthracene derivative, a triphenylene derivative, or the like. Each of the blue light emitting layers BEML1, BEML2, and BEML3 and the green light emitting layer GEML may further include, as a host material, a material generally used in the art. For example, each of the blue light emitting layers BEML1, BEML2, and BEML3 and the green light emitting layer GEML may further include, as a host material, at least one of Bis[2-(diphenylphosphino)phenyl] ether oxide (DPEPO), 4,4′-Bis(carbazol-9-yl)biphenyl (CBP), 1,3-Bis(carbazol-9-yl)benzene (mCP), 2,8-Bis(diphenylphosphoryl)dibenzo[b,d]furan (PPF), 4,4′,4″-Tris(carbazol-9-yl)-triphenylamine (TCTA) or (1,3,5-tris(1-phenyl-1H-benzo[d]imidazole-2-yl)benzene (TPBi). However, an embodiment is not limited thereto, and tris(8-hydroxyquinolino)aluminum (Alq₃), poly (N-vinylcarbazole (PVK), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-Methyl-9,10-bis(naphthalen-2-yl)anthracene (MADN), Hexaphenyl cyclotriphosphazene (CPI), 1,4-Bis(triphenylsilyl)benzene (UGH2), Hexaphenylcyclotrisiloxane (DPSiO₃), Octaphenylcyclotetra siloxane (DPSiO₄), or the like, may be used as a host material.

In an embodiment, the blue light emitting layers BEML1, BEML2, and BEML3 may include, as a generally used fluorescent dopant material, a styryl derivative (e.g., 1,4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi)), 4,4′-bis[2-(4-(N,N-diphenylamino)phenyl)vinyl]biphenyl (DPAVBi), perylene and a derivative thereof (e.g., 2,5,8,11-Tetra-t-butylperylene (TBP)), pyrene and a derivative thereof (e.g., 1,1-dipyrene, 1,4-dipyrenylbenzene, 1,4-Bis(N, N-Diphenylamino)pyrene), or the like.

The green light emitting layer GEML may include a generally used phosphorescent dopant material. For example, a metal complex including iridium (Ir), platinum (Pt), osmium (Os), gold (Au), titanium (Ti), zirconium (Zr), hafnium (Hf), europium (Eu), terbium (Tb), or thulium (Tm) may be used as the phosphorescent dopant. For example, iridium (III) bis(4,6-difluorophenylpyridinato-N,C2′)picolinate (FIrpic), Bis(2,4-difluorophenylpyridinato)-tetrakis(1-pyrazolyl)borate iridium (III) (Fir6), or platinum octaethyl porphyrin (PtOEP) may be used as the phosphorescent dopant.

Each of the electron transport regions ETR1, ETR2, ETR3, and ETR4 may have a single layer made of a single material, or a single layer made of multiple different materials, or a multilayer structure having multiple layers made of different materials. For example, at least a portion of the electron transport regions ETR1, ETR2, ETR3, and ETR4 may include an electron transport layer ETL4 and an electron injection layer EIL4.

Each of electron transport regions ETR1, ETR2, ETR3, and ETR4 may be provided using various methods such as vacuum deposition, spin coating, casting, Langmuir-Blodgett (LB), inkjet printing, laser printing, or laser induced thermal imaging (LITI).

The electron transport regions ETR1, ETR2, ETR3, and ETR4 may include anthracene-based compounds. However, an embodiment is not limited thereto, and each of the electron transport regions ETR1, ETR2, ETR3, and ETR4 may include, for example, Tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine (T2T), 2-(4-(N-phenylbenzoimidazol-1-yl)phenyl)-9,10-dinaphthylanthracene, 1,3,5-Tri(1-phenyl-1H-benzo[d]imidazol-2-yl)benzene (TPBi), 2,9-Dimethyl-4,7-diphenyl-1,10-phenanthroline (BCP), 4,7-Diphenyl-1,10-phenanthroline (Bphen), 3-(4-Biphenylyl)-4-phenyl-5-tert-butylphenyl-1,2,4-triazole (TAZ), 4-(Naphthalen-1-yl)-3,5-diphenyl-4H-1,2,4-triazole (NTAZ), 2-(4-Biphenylyl)-5-(4-tert-butylphenyl)-1,3,4-oxadiazole (tBu-PBD), Bis(2-methyl-8-quinolinolato-N1,O8)-(1,1′-Biphenyl-4-olato)aluminum (BAlq), berylliumbis(benzoquinolin-10-olate) (Bebq₂), 9,10-di(naphthalene-2-yl)anthracene (ADN), 1,3-Bis[3,5-di(pyridin-3-yl)phenyl]benzene (BmPyPhB), or a compound thereof.

Each of the electron transport regions ETR1, ETR2, ETR3, and ETR4 may include a halogenated metal such as LiF, NaCl, CsF, RbCl, RbI, CuI, or KI, a lanthanum group metal such as Yb, or a co-deposition material of the above halogenated metal and the lanthanum group metal. For example, the electron transport regions ETR1, ETR2, ETR3, and ETR4 may include KI:Yb, RbI:Yb, or the like as a co-deposition material. The electron transport regions ETR1, ETR2, ETR3, and ETR4 may include two or more materials selected from Mg, Ag, Yb, and Al. For example, the electron transport regions ETR1, ETR2, ETR3, and ETR4 may include Mg and Yb.

A metal oxide such as Li₂O, or BaO, 8-hydroxyl-Lithium quinolate (Liq), or the like may be used for the electron transport regions ETR1, ETR2, ETR3, and ETR4, but an embodiment is not limited thereto. Each of the electron transport regions ETR1, ETR2, ETR3 and ETR4 may also include a material in which an electron transport material and an insulating organo metal salt are mixed. The organo metal salt may be a material having an energy band gap of about 4 eV or more. For example, the organo metal salt may include metal acetate, metal benzoate, metal acetoacetate, metal acetylacetonate, or metal stearate.

Each of the electron transport regions ETR1, ETR2, ETR3, and ETR4 may further include, in addition to the foregoing materials, at least one of 2,9-dimethyl-4,7-diphenyl-1,10-phenanthroline (BCP) or 4,7-diphenyl-1,10-phenanthroline (Bphen), but an embodiment is not limited thereto.

In the electron transport regions ETR1, ETR2, ETR3, and ETR4, the foregoing compounds of the electron transport regions may be included in the electron injection layer or the electron transport layer. In a case in which each of the electron transport regions ETR1, ETR2, ETR3, and ETR4 includes the electron side additional layer, the electron side additional layer may include the foregoing material. In an embodiment, the electron injection layer EIL4 may include two or more materials selected from Mg, Ag, Yb, and Al. For example, the electron injection layer EIL4 may include a mixture of Mg and Yb.

Each of the electron transport regions ETR1, ETR2, ETR3, and ETR4 may have a thickness of, for example, about 10 nm to about 150 nm. The electron transport layer may have a thickness of about 0.1 nm to about 100 nm, for example, about 0.3 nm to 50 nm. In a case in which the thickness of the electron transport layer falls within the foregoing range, satisfactory electron transport characteristics may be obtained without significantly increasing a driving voltage.

The second electrode EL2 may be provided on the light emitting stacks ST1, ST2, ST3, and ST4. The second electrode EL2 may be a common electrode. The second electrode EL2 may be a cathode or an anode, but an embodiment is not limited thereto. For example, in a case in which the first electrode EL1 is an anode, the second electrode EL2 may be a cathode, and in a case in which the first electrode EL1 is a cathode, the second electrode EL2 may be an anode.

The second electrode EL2 may be a semi-transmissive electrode or a transmissive electrode. In a case in which the second electrode EL2 is a transmissive electrode, the second electrode EL2 may include a transparent metal oxide, for example, an indium tin oxide (ITO), an indium zinc oxide (IZO), a zinc oxide (ZnO), an indium tin zinc oxide (ITZO), or the like.

In a case in which the second electrode EL2 is a semi-transmissive electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, In, Zn, Sn, or a compound or mixture thereof (e.g., AgMg, AgYb or MgYb). In another embodiment, the second electrode EL2 may have a multilayer structure including a reflective film or a semi-transmissive film, each of which is made of the foregoing material, and a transparent conductive film made of an indium tin oxide (ITO), an indium zinc oxide (IZO), a zinc oxide (ZnO), an indium tin zinc oxide (ITZO) or the like. For example, the second electrode EL2 may include the foregoing metal material, a combination of two or more metal materials selected from the foregoing metal materials, an oxide of the foregoing metal materials, or the like.

Although not illustrated, the second electrode EL2 may be connected to an auxiliary electrode. In a case where the second electrode EL2 is connected to the auxiliary electrode, resistance of the second electrode EL2 may be reduced.

A capping layer CPL may be further disposed on the second electrode EL2 of the light emitting element LED according to an embodiment. The capping layer CPL may have a multilayer structure or a single-layer structure.

In an embodiment, the capping layer CPL may be an organic layer or an inorganic layer. For example, in a case in which the capping layer CPL includes an inorganic substance, the inorganic substance may include an alkaline metal compound such as LiF, an alkaline earth metal compound such as MgF₂, SiOₓN_{y}, SiNₓ, SiO_{y}, or the like.

For example, in a case in which the capping layer CPL includes an organic substance, the organic substance may include α-NPD, NPB, TPD, m-MTDATA, Alq₃, CuPc, N4,N4,N4′,N4′-tetra (biphenyl-4-yl) biphenyl-4,4′-diamine (TPD15), 4,4′,4″-tris (carbazol-9-yl)triphenylamine (TCTA), or the like, or may include an epoxy resin, or an acrylate such as a methacrylate.

The capping layer CPL may have a refractive index of about 1.6 or more. For example, the refractive index of the capping layer CPL with respect to light in a wavelength region of about 550 nm to about 660 nm may be about 1.6 or more.

Referring to FIG. 4A again, in the light emitting element LED according to an embodiment, the electron control layer ETR may be disposed between the light emitting layer EML and the second electrode EL2. The electron control layer ETR may include at least one of an electron injection layer, an electron transport layer, or a hole blocking layer. Referring to FIG. 4A, the electron control layer ETR may be disposed as a common layer to overlap the entirety of the light emitting areas EA1, EA2, and EA3 and the pixel defining layer PDL which divides the light emitting areas EA1, EA2, and EA3. However, an embodiment is not limited thereto, and the electron control layer ETR may be patterned and separately disposed to correspond to each of the light emitting areas EA1, EA2, and EA3.

The second electrode EL2 may be provided on the electron control layer ETR. The second electrode EL2 may be a common electrode. The second electrode EL2 may be a cathode or an anode, but an embodiment is not limited thereto. For example, in a case in which the first electrode EL1 is an anode, the second electrode EL2 may be a cathode, and in a case in which the first electrode EL1 is a cathode, the second electrode EL2 may be an anode. The second electrode EL2 may be a transmissive electrode, a semi-transmissive electrode, or a reflective electrode.

An encapsulation layer TFE may be disposed on the light emitting element LED. For example, in an embodiment, the encapsulation layer TFE may be disposed on the second electrode EL2. In a case in which the light emitting element LED includes a capping layer (not illustrated), the encapsulation layer TFE may be disposed on the capping layer (not illustrated). As described above, the encapsulation layer TFE may include at least one organic film and at least one inorganic film, and the inorganic film and the organic film may be alternately disposed.

The display panel DP according to an embodiment may include an optical structure layer OSL disposed on the display element layer DP-LED. The optical structure layer OSL may include a light control layer CCL, a color filter layer CFL, and a base layer BL.

A portion of the light control layer CCL may include a photoconversion material. The photoconversion material may be a quantum dot, a phosphor, or the like. The photoconversion material may convert a wavelength of received light and may emit light having the converted wavelength. For example, at least a portion of the light control layer CCL may include the quantum dot or include the phosphor.

The light control layer CCL may include multiple light control patterns CCP-R, CCP-G, and CCP-B. The light control patterns CCP-R, CCP-G, and CCP-B may be spaced apart from each other. The light control patterns CCP-R, CCP-G, and CCP-B may be disposed apart from each other by the bank BMP.

The light control patterns CCP-R, CCP-G, and CCP-B may be disposed within bank opening portions BOH1, BOH2, and BOH3 defined by the bank BMP, respectively. However, an embodiment is not limited thereto. At least a portion of an edge of a portion of the light control patterns CCP-R, CCP-G, and CCP-B may overlap the bank BMP. For example, as illustrated in FIG. 4A, an edge of a third light control pattern CCP-B may overlap the bank BMP when viewed in a plan view. However, an embodiment is not limited thereto, and the bank BMP may not overlap the light control patterns CCP-R, CCP-G, and CCP-B when viewed in a plan view.

The bank BMP may include a base resin and an additive. The base resin may include various resin compositions generally referred to as binders. The additive may include a coupling agent and/or a photoinitiator. The additive may further include a dispersing agent.

In an embodiment, the bank BMP included in the light control layer CCL may be optically transparent. The bank BMP may include an optically transparent material. The base resin included in the bank BMP may be optically transparent. The bank BMP may include a material having a transmittance of about 85% or more in a visible light range. The bank BMP may not include a separate coloring agent. The bank BMP may not include a black dye or black pigment mixed in the base resin. In an embodiment, the bank BMP may not include a light blocking material such as carbon black having a black color, or a dye or a pigment having a blue color.

In the display panel DP according to an embodiment, a stepped portion may be partially generated between a top surface (or upper surface) of the bank BMP and a top surface (or upper surface) of each of the light control patterns CCP-R, CCP-G, and CCP-B. For example, the top surface of the bank BMP may be higher than the top surface of at least a portion of the light control patterns CCP-R, CCP-G, and CCP-B. A height difference between the top surface of the bank BMP and the top surface of the light control patterns CCP-R, CCP-G, and CCP-B may be, for example, about 2 μm to about 3 μm.

The light control patterns CCP-R, CCP-G, and CCP-B may each be a portion that converts a wavelength of the light provided from the display element layer DP-OLED or transmits the provided light.

The light control layer CCL may include a first light control pattern CCP-R which provides red light as first light, a second light control pattern CCP-G which provides green light as second light, and a third light control pattern CCP-B which provides blue light as third light. The light control layer CCL may include the first light control pattern CCP-R which converts the source light, i.e., the third light, provided from the light emitting element LED, to the first light, the second light control pattern CCP-G which converts the source light to the second light, and the third light control pattern CCP-B which transmits the source light.

Some of the light control patterns CCP-R, CCP-G, and CCP-B may be formed through an inkjet process. In an embodiment, the first light control pattern CCP-R and the second light control pattern CCP-G may be formed through the inkjet process. A first ink composition in a liquid state may be provided inside the first bank opening portion BOH1, and the provided ink composition may be polymerized through a thermal curing process or a light curing process to form the first light control pattern CCP-R. A second ink composition in a liquid state may be provided inside the second bank opening portion BOH2, and the provided ink composition may be polymerized through a thermal curing process or a light curing process to form the second light control pattern CCP-G. The first ink composition used for forming the first light control pattern CCP-R and the second ink composition used for forming the second light control pattern CCP-G may be different. For example, the first ink composition may include a first quantum dot QD1, and the second ink composition may include a second quantum dot QD2 different from the first quantum dot QD1.

The other light control patterns CCP-R, CCP-G, and CCP-B may be formed through a photoresist process. In an embodiment, the third light control pattern CCP-B may be formed through the photoresist process. A photoresist composition may be provided inside at least the third bank opening portion BOH3, and the provided photoresist composition may be cured to form the third light control pattern CCP-B. However, an embodiment is not limited thereto, and each of the light control patterns CCP-R, CCP-G, and CCP-B may be formed through the inkjet process. In an embodiment, each of the first to third light control patterns CCP-R, CCP-G, and CCP-B may be formed through the inkjet process.

A portion of the bank BMP may overlap at least a portion of the light control patterns CCP-R, CCP-G, and CCP-B when viewed in a plan view. As illustrated in FIG. 4A, a portion of the bank BMP may overlap the third light control pattern CCP-B in a plan view. A portion of the third light control pattern CCP-B may be disposed above the bank BMP. In the light control layer CCL according to an embodiment, the bank BMP may include a transparent material and overlap the third light control pattern CCP-B, which is formed through the photoresist process, when viewed in a plan view. However, an embodiment is not limited thereto. The bank BMP may not overlap any of the light control patterns CCP-R, CCP-G, and CCP-B when viewed in a plan view.

Some of the light control patterns CCP-R, CCP-G, and CCP-B may include a quantum dot that converts the source light to light having a specific wavelength range. As described above, the first light control pattern CCP-R may include the first quantum dot QD1, which converts the source light to light having a first wavelength, and the second light control pattern CCP-G may include the second quantum dot QD2, which converts the source light to light having a second wavelength.

Each of the light control patterns CCP-R, CCP-G, and CCP-B may further include a scatterer SP. The first light control pattern CCP-R may include the first quantum dot QD1 and the scatterer SP, the second light control pattern CCP-G may include the second quantum dot QD2 and the scatterer SP, and the third light control pattern CCP-B may not include a quantum dot but include the scatterer SP.

The first light control pattern CCP-R, the second light control pattern CCP-G, and the third light control pattern CCP-B may further include base resins BR1, BR2, and BR3, respectively, which disperse the quantum dots QD2 and QD2 and the scatterer SP. The first light control pattern CCP-R may include a first base resin BR1 which disperses the first quantum dot QD1 and the scatterer SP, the second light control pattern CCP-G may include a second base resin BR2 which disperses the second quantum dot QD2 and the scatterer SP, and the third light control pattern CCP-B may include a third base resin BR3 which disperses the scatterer SP. In a case in which the third light control pattern CCP-B is formed through the photoresist process, the third light control pattern CCP-B may include a photosensitive resin.

Referring to FIGS. 2A, 2B, and 4A together, the light control layer CCL may include a metal pattern MP. The metal pattern MP may be disposed between each of the light control patterns CCP-R, CCP-G, and CCP-B, and the bank BMP. A first metal pattern MP1 may be disposed between the first light control pattern CCP-R and the bank BMP, a second metal pattern MP2 may be disposed between the second light control pattern CCP-G and the bank BMP, and a third metal pattern MP3 may be disposed between the third light control pattern CCP-B and the bank BMP.

The metal pattern MP may include a reflective metal. The metal pattern MP may include a reflective metal having high reflectance. For example, the metal pattern MP may include Ag, Mg, Cu, Al, Pt, Pd, Au, Ni, Nd, Ir, Cr, Li, Ca, LiF/Ca, LiF/Al, Mo, Ti, W, In, Zn, Sn, or a compound or mixture thereof (e.g., a mixture of Ag and Mg), all of which have high reflectance.

The metal pattern MP may be disposed between adjacent light control patterns CCP-R, CCP-G, and CCP-B, thereby preventing color mixture between the adjacent light control patterns CCP-R, CCP-G, and CCP-B and increasing the efficiency of light emitted to the outside. By providing the metal pattern MP between the adjacent light control patterns CCP-R, CCP-G, and CCP-B, color mixture between adjacent pixel areas may be prevented. As the metal pattern MP includes the reflective metal, the source light emitted from the display element layer DP-LED may be recycled through the metal pattern MP, thereby increasing the efficiency of light emitted through the bank opening portions BOH1, BOH2, and BOH3 to the outside. The metal pattern MP may surround a portion of each of the light control patterns CCP-R, CCP-G, and CCP-B when viewed in a plan view. The metal pattern MP may surround a portion of each of the light control patterns CCP-R, CCP-G, and CCP-B but may not surround the remaining portions. The metal pattern MP may include the first metal pattern MP1 which surrounds a portion of the first light control pattern CCP-R, the second metal pattern MP2 which surrounds a portion of the second light control pattern CCP-G, and the third metal pattern MP3 which surrounds a portion of the third light control pattern CCP-B. The first metal pattern MP1, the second metal pattern MP2, and the third metal pattern MP3 may surround the portions of the first light control pattern CCP-R, the second light control pattern CCP-G, and the third light control pattern CCP-B, respectively, but may not surround the remaining portions.

A portion of the metal pattern MP may overlap the bank BMP when viewed in a plan view. A portion of each of the first to third metal patterns MP1, MP2, and MP3 may overlap the bank BMP in a plan view. A portion of the metal pattern MP may overlap at least a portion of each of the light control patterns CCP-R, CCP-G, and CCP-B in a plan view. A portion of the first metal pattern MP1 may overlap at least a portion of the first light control pattern CCP-R, a portion of the second metal pattern MP2 may overlap at least a portion of the second light control pattern CCP-G, and a portion of the third metal pattern MP3 may overlap at least a portion of the third light control pattern CCP-B. However, an embodiment is not limited thereto, and the metal pattern MP may not overlap the bank BMP and/or the light control patterns CCP-R, CCP-G, and CCP-B in a plan view.

An open portion OPP which does not surround the light control patterns CCP-R, CCP-G, and CCP-B may be defined in the metal pattern MP. A first open portion OP1 which does not surround the first light control pattern CCP-R may be defined in the first metal pattern MP1, a second open portion OP2 which does not surround the second light control pattern CCP-G may be defined in the second metal pattern MP2, and a third open portion OP3 which does not surround the third light control pattern CCP-B may be defined in the third metal pattern MP3.

The open portions OP1, OP2, and OP3 defined in the metal pattern MP may not face each other in a plan view. In the first metal pattern MP1, the second metal pattern MP2, and the third metal pattern MP3 surrounding, respectively, the first light control pattern CCP-R, the second light control pattern CCP-G, and the third light control pattern CCP-B which are disposed adjacent to each other, the first open portion OP1, the second open portion OP2, and the third open portion OP3 defined in the first metal pattern MP1, the second metal pattern MP2, and the third metal pattern MP3, respectively, are positioned so as not to face each other in a plan view.

In the disclosure, in a case where the open portions are defined “so as not to face each other in a plan view”, it means that the open portions do not overlap each other at a portion at which a shortest distance between adjacent light control patterns is defined. For example, the first open portion OP1 may be defined in the first metal pattern MP1, and no open portion may be defined at each of a portion of the second metal pattern MP2 and/or a portion of the third metal pattern MP3 which are closest to a portion in which the first open portion OP1 is located. Likewise, no open portion may be defined in each of a portion of the first metal pattern MP1 and/or a portion of the third metal pattern MP3 which are closest to a portion in which the second open portion OP2 is located, and no open portion may be defined in each of a portion of the first metal pattern MP1 and/or a portion of the second metal pattern MP2 which are closest to a portion in which the third open portion OP3 is located.

In the first metal patterns MP1 surrounding two adjacent first light control patterns CCP-R, respectively, the first open portion OP1 defined in the first metal pattern MP1 surrounding one of the two first light control patterns CCP-R, and the first open portion OP1 defined in the first metal pattern MP1 surrounding the other first light control pattern CCP-R may not face each other. In the second metal patterns MP2 surrounding two adjacent second light control patterns CCP-G, respectively, the second open portion OP2 defined in the second metal pattern MP2 surrounding one of the two second light control patterns CCP-G, and the second open portion OP2 defined in the second metal pattern MP2 surrounding the other second light control pattern CCP-G, may not face each other. In the third metal patterns MP3 surrounding two adjacent third light control patterns CCP-B, respectively, the third open portion OP3 defined in the third metal pattern MP3 surrounding one of the two third light control patterns CCP-B, and the third open portion OP3 defined in the third metal pattern MP3 surrounding the other third light control pattern CCP-B, may not face each other.

The open portions OP1, OP2, and OP3 may face at least a portion of the metal patterns MP1, MP2, and MP3 between adjacent light control patterns CCP-R, CCP-G, and CCP-B. For example, as illustrated in FIGS. 2A, 2B, and 4A, between the first light control pattern CCP-R and the second light control pattern CCP-G, the first open portion OP1 may face at least a portion of the second metal pattern MP2, or the second open portion OP2 may face at least a portion of the first metal pattern MP1. Also, between the second light control pattern CCP-G and the third light control pattern CCP-B, the second open portion OP2 may face at least a portion of the third metal pattern MP3, or the third open portion OP3 may face at least a portion of the second metal pattern MP2. Also, between the third light control pattern CCP-B and the first light control pattern CCP-R, the third open portion OP3 may face at least a portion of the first metal pattern MP1, or the first open portion OP1 may face at least a portion of the third metal pattern MP3.

In an embodiment, a metal pattern may be disposed between the adjacent light control patterns CCP-R, CCP-G, and CCP-B. One of the first metal pattern MP1 and the second metal pattern MP2 may be disposed between the first light control pattern CCP-R and the second light control pattern CCP-G. One of the second metal pattern MP2 and the third metal pattern MP3 may be disposed between the second light control pattern CCP-G and the third light control pattern CCP-B. One of the third metal pattern MP3 and the first metal pattern MP1 may be disposed between the third light control pattern CCP-B and the first light control pattern CCP-R. For example, as illustrated in FIG. 2A, the first metal pattern MP1 may be disposed between the first light control pattern CCP-R and the second light control pattern CCP-G, the second metal pattern MP2 may be disposed between the second light control pattern CCP-G and the third light control pattern CCP-B, and the third metal pattern MP3 may be disposed between the third light control pattern CCP-B and the first light control pattern CCP-R.

In the open portions OP1, OP2, and OP3, each of the light control patterns CCP-R, CCP-G, and CCP-B may be in contact with at least a portion of the bank BMP. In the first open portion OP1, the first light control pattern CCP-R may be in contact with at least a portion of the bank BMP. In the second open portion OP2, the second light control pattern CCP-G may be in contact with at least a portion of the bank BMP. In the third open portion OP3, the third light control pattern CCP-B may be in contact with at least a portion of the bank BMP.

Each of the first open portion OP1, the second open portion OP2, and the third open portion OP3 may be defined at one side of each of the first light control pattern CCP-R, the second light control pattern CCP-G, and the third light control pattern CCP-B. For example, as illustrated in FIGS. 2A and 2B, the first open portion OP1 may be defined adjacent to one of two short sides of the first light control pattern CCP-R extending in the first direction DR1 and spaced apart from each other in the second direction DR2, and two long sides thereof extending in the second direction DR2 and spaced apart from each other in the first direction DR1. The second open portion OP2 may be defined adjacent to one of two short sides of the second light control pattern CCP-G extending in the first direction DR1 and spaced apart from each other in the second direction DR2, and two long sides thereof extending in the second direction DR2 and spaced apart from each other in the first direction DR1. The third open portion OP3 may be defined adjacent to one of two short sides of the third light control pattern CCP-B extending in the first direction DR1 and spaced apart from each other in the second direction DR2, and two long sides thereof extending in the second direction DR2 and spaced apart from each other in the first direction DR1.

Shapes of the first to third metal patterns MP1, MP2, and MP3 may vary in a plan view. For example, as illustrated in FIG. 2A, planar shapes of the first metal pattern MP1, the second metal pattern MP2, and the third metal pattern MP3 which are included in one pixel unit PXA-U may be the same. The planar shapes of the first to third metal patterns MP1, MP2, and MP3 which are included in the one pixel unit PXA-U may be different, respectively, from planar shapes of the first to third metal patterns MP1, MP2, and MP3 which are included in an adjacent pixel unit PXA-U. For example, the planar shape of the first metal pattern MP1 included in the one pixel unit PXA-U may be different from the planar shape of the first metal pattern MP1 included in the adjacent pixel unit PXA-U. Likewise, each of the planar shapes of the second metal pattern MP2 and the third metal pattern MP3 included in the one pixel unit PXA-U may be different from the planar shape of the second metal pattern MP2 included in the adjacent pixel unit PXA-U.

The light control layer CCL may include the first barrier layer CAP1 disposed on one surface of the light control patterns CCP-R, CCP-G, and CCP-B. The light control layer CCL may include the first barrier layer CAP1 spaced apart from the display element layer DP-LED and the second barrier layer CAP2 adjacent to the display element layer DP-LED, with the light control patterns CCP-R, CCP-G, and CCP-B between the first and second barrier layers. The first barrier layer CAP1 may be disposed to follow a stepped portion between the bank BMP and each of the light control patterns CCP-R, CCP-G, and CCP-B. The first barrier layer CAP1 may be disposed (or directly disposed) below the filling layer FML.

In the display panel DP, the optical structure layer OSL may include the color filter layer CFL disposed on the light control layer CCL. The color filter layer CFL may include color filters CF1, CF2, and CF3. The color filter layer CFL may include a first color filter CF1 which transmits the first light, a second color filter CF2 which transmits the second light, and a third color filter CF3 which transmits the source light. In an embodiment, the first color filter CF1 may be a red filter, the second color filter CF2 may be a green filter, and the third color filter CF3 may be a blue filter.

Each of the color filters CF1, CF2, and CF3 may include a polymer photosensitive resin and a colorant. The first color filter CF1 may include a blue colorant, the second color filter CF2 may include a red colorant, and the third color filter CF3 may include a green colorant. The first color filter CF1 may include a blue pigment or a blue dye, the second color filter CF2 may include a red pigment or a red dye, and the third color filter CF3 may include a green pigment or a green dye.

The first to third color filters CF1, CF2, and CF3 may be disposed to correspond to the first pixel area PXA-R, the second pixel area PXA-G, and the third pixel area PXA-B, respectively. The first to third color filters CF1, CF2, and CF3 may be disposed to correspond to the first to third light control patterns CCP-R, CCP-G, and CCP-B, respectively.

Multiple color filters CF1, CF2, and CF3, which transmit different light, may be disposed to overlap each other at a non-light emitting area NPXA disposed between the pixel areas PXA-R, PXA-G, and PXA-B. The color filters CF1, CF2, and CF3 may overlap each other in the third direction DR3, that corresponds to a thickness direction, to form a boundary between adjacent pixel areas PXA-R, PXA-G and PXA-B. In some embodiments, the color filter layer CFL may include a light blocking part (not illustrated) as a component to define a boundary between adjacent color filters CF1, CF2, and CF3. The light blocking part (not illustrated) may be provided as a blue filter or may include an organic light blocking material or an inorganic light blocking material each including a black pigment or a black dye.

The optical structure layer OSL may include the filling layer FML disposed between the light control layer CCL and the color filter layer CFL. The filling layer FML may be disposed between the light control patterns CCP-R, CCP-G, and CCP-B and the color filters CF1, CF2, and CF3. The filling layer FML may be disposed on the light control layer CCL and prevent the light control patterns CCP-R, CCP-G, and CCP-B from being exposed to moisture or oxygen. The filling layer FML may be disposed between the light control patterns CCP-R, CCP-G, and CCP-B and the color filters CF1, CF2, and CF3 and may function as an optical functional layer, for example, by increasing the light extraction efficiency or reducing the incidence of reflected light on the light control layer CCL. The filling layer FML may have a lower refractive index compared to adjacent layers.

In an embodiment, the optical structure layer OSL may further include the base layer BL disposed on the color filter layer CFL. The base layer BL may form a base surface on which the color filter layer CFL, the light control layer CCL, and the like are disposed. The base layer BL may be made of a glass substrate, a metal substrate, a plastic substrate, or the like. However, an embodiment is not limited thereto, and the base layer BL may be an inorganic layer, an organic layer, or a composite material layer. In another embodiment, the base layer BL may be omitted.

FIGS. 4B to 4D illustrate display panels DP-1, DP-2, and DP-3 according to an embodiment that differs from the display panel DP according to an embodiment illustrated in FIG. 4A.

Referring to FIG. 4B, the display panel DP-1 according to an embodiment may include a lower panel, which includes a base substrate BS, a circuit element layer DP-CL disposed on the base substrate BS, and a display element layer DP-LED disposed on the circuit element layer DP-CL, and an optical structure layer OSL-1 disposed on the lower panel. The optical structure layer OSL-1 may include a light control layer CCL-1, a color filter layer CFL, and a base layer BL.

The display panel DP-1 according to an embodiment may include the lower panel including the display element layer DP-LED, and an upper panel OSL-1 (optical structure layer) including the light control layer CCL-1 and the color filter layer CFL. In an embodiment, a filling layer FML-1 may be disposed between the lower panel and the upper panel OSL-1.

In an embodiment, the filling layer FML-1 may fill a space between the display element layer DP-LED and the light control layer CCL-1. The filling layer FML-1 may be disposed (or directly disposed) on an encapsulation layer TFE, and a first barrier layer CAP1 may be disposed (directly disposed) on the filling layer FML-1. A bottom surface (or lower surface) of the filling layer FML-1 may be in contact with a top surface (or upper surface) of the encapsulation layer TFE, and a top surface (or upper surface) of the filling layer FML-1 may be in contact with a bottom surface (or lower surface) of the first barrier layer CAP1.

The filling layer FML-1 may function as a buffer between the display element layer DP-LED and the light control layer CCL-1. In an embodiment, the filling layer FML-1 may perform a shock absorbing function or the like, and may increase the strength of the display panel DP-1. The filling layer FML-1 may be formed from a filling resin including a polymer resin. For example, the filling layer FML-1 may be formed from a filling layer resin including an acryl-based resin, an epoxy-based resin, or the like.

Compared to the display panel DP illustrated in FIG. 4A, the display panel DP-1 according to an embodiment illustrated in FIG. 4B may represent an embodiment in which the filling layer FML-1 is disposed between the display element layer DP-LED and the light control layer CCL-1. For example, the display panel DP-1 in FIG. 4B may be provided by disposing the circuit element layer DP-CL and the display element layer DP-LED in sequence on a surface of base substrate BS as a base surface to form the lower panel, disposing the color filter layer CFL and the light control layer CCL-1 in sequence on a surface of the base layer BL as a base surface to form the upper panel OSL-1 (optical structure layer), and coupling the lower panel and the upper panel with the filling layer FML-1 between the lower panel and the upper panel.

In the display panel DP-1 according to an embodiment, a stepped portion may be partially generated between a bottom surface (or lower surface) of a bank BMP and a bottom surface (or lower surface) of each of light control patterns CCP-R, CCP-G, and CCP-B. For example, the bottom surface of the bank BMP may be lower than the bottom surface of each of the light control patterns CCP-R, CCP-G, and CCP-B. A height difference between the bottom surface of the bank BMP and the bottom surface of each of the light control patterns CCP-R, CCP-G, and CCP-B may be, for example, about 2 μm to about 3 μm.

The first barrier layer CAP1 may follow the stepped portion between the bank BMP and each of the light control patterns CCP-R, CCP-G, and CCP-B. The first barrier layer CAP1 may be disposed (or directly disposed) on the filling layer FML-1.

The display panel DP-1 according to an embodiment may include a low refractive layer LR. The low refractive layer LR may be disposed between the light control layer CCL-1 and the color filter layer CFL. The low refractive layer LR may be disposed on the light control layer CCL-1 and may prevent the light control patterns CCP-R, CCP-G, and CCP-B from being exposed to moisture or oxygen. The low refractive layer LR may be disposed between the light control patterns CCP-R, CCP-G, and CCP-B and color filters CF1, CF2, and CF3 to function as an optical functional layer that, for example, increases the light extraction efficiency or prevents incidence of reflected light on the light control layer CCL-1. The low refractive layer LR may have a lower refractive index compared to an adjacent layer.

The low refractive layer LR may include at least one inorganic layer. For example, the low refractive layer LR may include silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, or a metal thin film having light transmittance or the like. However, an embodiment is not limited thereto, and the low refractive layer LR may include an organic film. The low refractive layer LR may have, for example, a structure in which multiple hollow particles are dispersed in an organic polymeric resin. The low refractive layer LR may include a single layer or multiple layers.

Referring to FIG. 4C, the display panel DP-2 according to an embodiment may include a lower panel, which includes a base substrate BS, a circuit element layer DP-CL disposed on the base substrate BS, and a display element layer DP-LED disposed on the circuit element layer DP-CL, and an optical structure layer OSL-2 disposed on the lower panel. In the display panel DP-2 according to an embodiment, the optical structure layer OSL-2 may include a light control layer CCL, a filling layer FML, a color filter layer CFL-1, and a base layer BL-1 which are stacked in sequence on a thin-film encapsulation layer TFE.

The light control layer CCL may be disposed on the display element layer DP-LED. The light control layer CCL may be disposed on the thin-film encapsulation layer TFE included in the display element layer DP-LED. The light control layer CCL may be disposed (or directly disposed) on the thin-film encapsulation layer TFE. The light control layer CCL may include multiple banks BMP and light control patterns CCP-R, CCP-G, and CCP-B, each of which is disposed between the banks BMP. The light control layer CCL may further include a first barrier layer CAP1 and a second barrier layer CAP2 which are disposed, respectively, on a top surface (or upper surface) and a bottom surface (or lower surface) of the light control patterns CCP-R, CCP-G, and CCP-B. The filling layer FML may be disposed on the light control layer CCL.

The color filter layer CFL-1 may include multiple color filters CF1, CF2, and CF3 and a light blocking part BM.

Compared to the display panel DP-1 illustrated in FIG. 4B, the display panel DP-2 according to an embodiment illustrated in FIG. 4C corresponds to an embodiment in which the light control layer CCL, a low refractive layer LR-1, and the color filter layer CFL-1 are disposed on a top surface (or upper surface) of the thin-film encapsulation layer TFE as a base surface. For example, the light control patterns CCP-R, CCP-G, and CCP-B of the light control layer CCL may be formed on the thin-film encapsulation layer TFE through a continuous process, and the color filters CF1, CF2, and CF3 of the color filter layer CFL-1 may be formed in sequence on the light control layer CCL through a continuous process. The color filter layer CFL-1 may be disposed on a top surface (or upper surface) of the low refractive layer LR-1 as a base surface and have a different shape from those illustrated in FIGS. 4A and 4B.

In the color filter layer CFL-1 according to an embodiment, the light blocking part BM may be a black matrix. The light blocking part BM may include an organic light blocking material or an inorganic light blocking material each including a black pigment or a black dye. The light blocking part BM may prevent light leakage and define a boundary between adjacent color filters CF1, CF2, and CF3.

Referring to FIG. 4D, a display element layer DP-LED1 included in the display panel DP-3 according to an embodiment may include a light emitting element LED-1, where the light emitting element LED-1 may be a micro LED element or a nano LED element. The light emitting element LED-1 may be disposed between pixel defining films PDL and electrically connected to a contact portion S-C. A length and a width of the light emitting element LED-1 may range from hundreds of nanometers to hundreds of micrometers. The light emitting element LED-1 may be an LED element including an active layer and at least one semiconductor material layer. The light emitting element LED-1 may further include an insulation layer that covers respective surfaces of the active layer and the semiconductor material layer. The light emitting element LED-1 may be patterned to overlap each of pixel areas PXA-R, PXA-G and PXA-B. The display panel DP-3 may include a buffer layer BFL disposed on the light emitting element LED-1. The buffer layer BFL may be disposed on the light emitting element LED-1 to cover the light emitting element LED-1. In the display panel DP-3 according to an embodiment illustrated in FIG. 4D, the buffer layer BFL may be omitted.

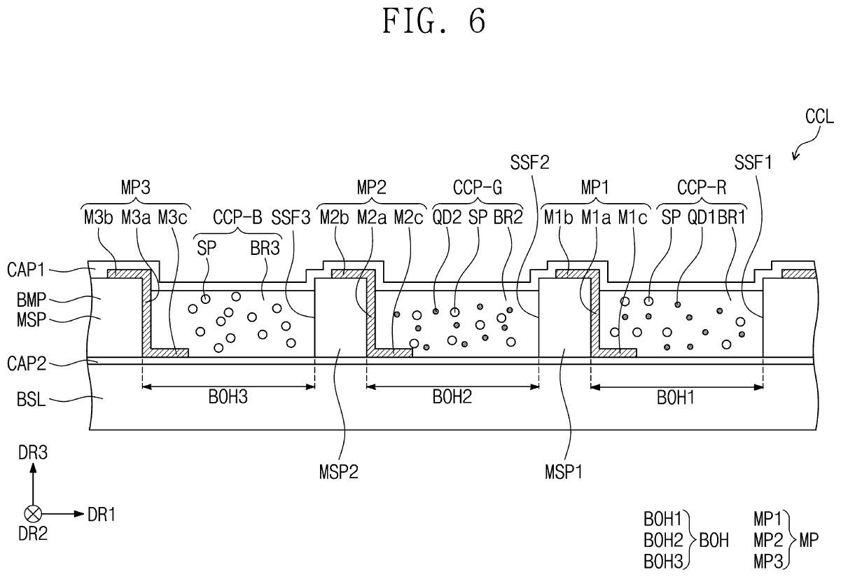

FIG. 6 is a schematic enlarged partial cross-sectional view of components of a display panel according to an embodiment. FIG. 6 illustrates a cross-section corresponding to FIG. 4A, focusing on components included in the light control layer CCL (see FIG. 4A) of the display panel according to an embodiment.

Referring to FIGS. 2A, 2B, 4A, and 6 together, a light control layer CCL may include multiple light control patterns CCP-R, CCP-G, and CCP-B, a bank BMP, and a metal pattern MP. The light control layer CCL may further include a first barrier layer CAP1 and a second barrier layer CAP2.

The light control layer CCL may be disposed on a base member BSL. The base member BSL may be a member that provides a base surface for the light control layer CCL. The base member BSL may correspond to the thin-film encapsulation layer TFE described above with reference to FIG. 4A or the low refractive layer LR described above with reference to FIG. 4B.

The light control patterns CCP-R, CCP-G, and CCP-B included in the light control layer CCL may be spaced apart from each other. The light control patterns CCP-R, CCP-G, and CCP-B may be disposed apart from each other by the bank BMP.

The bank BMP may include a base resin and an additive. The base resin may include various resin compositions generally referred to as binders. The additive may include a coupling agent and/or a photoinitiator. The additive may further include a dispersing agent.

In an embodiment, the bank BMP included in the light control layer CCL may be optically transparent. The bank BMP may include an optically transparent material. The base resin included in the bank BMP may be optically transparent. The bank BMP may have a transmittance of about 85% or more in a visible light range. The bank BMP may not include a separate coloring agent. The bank BMP may not include a black dye or black pigment mixed in the base resin. In an embodiment, the bank BMP may not include a light blocking material such as carbon black having a black color, or a dye or a pigment having a blue color or the like.

A bank opening portion BOH may be defined in the bank BMP. First to third bank opening portions BOH1, BOH2, and BOH3 corresponding to first to third pixel areas PXA-R, PXA-G, and PXA-B, respectively, may be defined in the bank BMP. The bank BMP may include a first inner side surface SSF1 which defines the first bank opening portion BOH1, a second inner side surface SSF2 which defines the second bank opening portion BOH2, and a third inner side surface SSF3 which defines the third bank opening portion BOH3. In the light control layer CCL according to an embodiment, the bank BMP may include a transparent material.

The light control patterns CCP-R, CCP-G, and CCP-B may be disposed, respectively, in the bank opening portions BOH1, BOH2, and BOH3 defined by the bank BMP. The first light control pattern CCP-R may be disposed in the first bank opening portion BOH1, the second light control pattern CCP-G may be disposed in the second bank opening portion BOH2, and the third light control pattern CCP-B may be disposed in the third bank opening portion BOH3.

Some of the light control patterns CCP-R, CCP-G, and CCP-B may be formed through an inkjet process. In an embodiment, the first light control pattern CCP-R and the second light control pattern CCP-G may each be formed through the inkjet process. An ink composition in a liquid state may be provided inside each of the first bank opening portion BOH1 and the second bank opening portion BOH2, and the provided ink composition may be polymerized through a thermal curing process or a light curing process to form the first light control pattern CCP-R and the second light control pattern CCP-G. The ink composition used for the first light control pattern CCP-R and the ink composition used for the second light control pattern CCP-G may be different.

The other light control pattern among the light control patterns CCP-R, CCP-G, and CCP-B may be formed through a photoresist process. In an embodiment, the third light control pattern CCP-B may be formed through the photoresist process. A photoresist composition may be provided to at least the inside of the third bank opening portion BOH3, and the provided photoresist composition may be cured to form the third light control pattern CCP-B. A light control pattern, which is formed through the photoresist process, of the light control patterns CCP-R, CCP-G, and CCP-B may overlap the bank BMP in a plan view. In an embodiment, the third light control pattern CCP-B formed through the photoresist process may overlap the bank BMP in a plan view. However, an embodiment is not limited thereto, and each of the light control patterns CCP-R, CCP-G, and CCP-B may not overlap the bank BMP in a plan view.

In an embodiment, the display panel DP may include a stepped portion between a top surface (or upper surface) of the bank BMP and a top surface (or upper surface) of each of the light control patterns CCP-R, CCP-G, and CCP-B. The top surface of the bank BMP may be higher than the top surfaces of at least some of the light control patterns CCP-R, CCP-G, and CCP-B. For example, as illustrated in FIG. 6, the bank BMP may have a greater thickness than each of the first light control pattern CCP-R and the second light control pattern CCP-G, and thus the top surface of the bank BMP may be higher than the top surfaces of the first light control pattern CCP-R and the second light control pattern CCP-G.

As described above, the first light control pattern CCP-R may include a first quantum dot QD1 that converts source light to light having a first wavelength. The second light control pattern CCP-G may include a second quantum dot QD2 that converts the source light to light having a second wavelength. Each of the light control patterns CCP-R, CCP-G, and CCP-B may further include a scatterer SP. The first light control pattern CCP-R may include the first quantum dot QD1 and the scatterer SP. The second light control pattern CCP-G may include the second quantum dot QD2 and the scatterer SP. The third light control pattern CCP-B may not include a luminant such as a quantum dot, but may include the scatterer SP. The first light control pattern CCP-R, the second light control pattern CCP-G, and the third light control pattern CCP-B may further include base resins BR1, BR2, and BR3, respectively, which disperse the quantum dots QD1 and QD2 and the scatterer SP.

In an embodiment, the light control layer CCL may include the first to third light control patterns CCP-R, CCP-G, and CCP-B, where some may be formed through an inkjet process. For example, each of the first light control pattern CCP-R corresponding to a red pixel area and the second light control pattern CCP-G corresponding to a green pixel area may include a quantum dot and may be formed through the inkjet process, and the third light control pattern CCP-B corresponding to a blue pixel area may include no quantum dot and may be formed through the photoresist process. However, an embodiment is not limited thereto, and in the light control layer CCL, all the first to third light control patterns CCP-R, CCP-G, and CCP-B may be formed through the inkjet process.

A light control pattern, which is formed through the photoresist process, of the first to third light control patterns CCP-R, CCP-G, and CCP-B may include a photosensitive resin. For example, as described above, the third light control pattern CCP-B, formed through the photoresist process, may include the photosensitive resin. The third base resin BR3 included in the third light control pattern CCP-B may be the photosensitive resin. Each of the first base resin BR1 included in the first light control pattern CCP-R and the second base resin BR2 included in the second light control pattern CCP-G may be resins for inkjet printing.

The light control layer CCL may include the metal pattern MP. A portion of the metal pattern MP may overlap the bank BMP in a plan view. The metal pattern MP may include a first metal pattern MP1 between the first light control pattern CCP-R and the bank BMP, a second metal pattern MP2 disposed between the second light control pattern CCP-G and the bank BMP, and a third metal pattern MP3 disposed between the third light control pattern CCP-B and the bank BMP.

The metal pattern MP may be disposed on the inner side surfaces SSF1, SSF2, and SSF3 of the bank BMP. The first metal pattern MP1 may be disposed on the first inner side surface SSF1. The first metal pattern MP1 may be disposed between the first inner side surface SSF1 and the first light control pattern CCP-R. The second metal pattern MP2 may be disposed on the second inner side surface SSF2. The second metal pattern MP2 may be disposed between the second inner side surface SSF2 and the second light control pattern CCP-G. The third metal pattern MP3 may be disposed on the third inner side surface SSF3. The third metal pattern MP3 may be disposed between the third inner side surface SSF3 and the third light control pattern CCP-B.

The metal pattern MP may surround a portion of each of the light control patterns CCP-R, CCP-G, and CCP-B in a plan view. The first metal pattern MP1 may surround a portion of the first light control pattern CCP-R, the second metal pattern MP2 may surround a portion of the second light control pattern CCP-G, and the third metal pattern MP3 may surround a portion of the third light control pattern CCP-B.

Open portions OP1, OP2, and OP3, which do not surround the light control patterns CCP-R, CCP-G, and CCP-B, may be defined in the metal patterns MP1, MP2, and MP3, respectively. Portions of the inner side surfaces SSF1, SSF2, and SSF3 of the bank BMP may be exposed by the open portions OP1, OP2, and OP3 defined in the metal patterns MP1, MP2, and MP3, respectively. A first open portion OP1, which does not surround the first light control pattern CCP-R, may be defined in the first metal pattern MP1, a second open portion OP2, which does not surround the second light control pattern CCP-G, may be defined in the second metal pattern MP2, and a third open portion OP3, which does not surround the third light control pattern CCP-B, may be defined in the third metal pattern MP3. The first open portion OP1, the second open portion OP2, and the third open portion OP3 may be spaced apart so as not to face each other in a plan view.

The metal patterns MP1, MP2, and MP3 may be in contact with portions of the inner side surfaces SSF1, SSF2, and SSF3 of the bank BMP which define the bank opening portions BOH1, BOH2, and BOH3, respectively. The first metal pattern MP1 may be disposed between the first inner side surface SSF1 and the first light control pattern CCP-R, and may be in contact with a portion of the first inner side surface SSF1. The second metal pattern MP2 may be disposed between the second inner side surface SSF2 and the second light control pattern CCP-G, and may be in contact with a portion of the second inner side surface SSF2. The third metal pattern MP3 may be disposed between the third inner side surface SSF3 and the third light control pattern CCP-B, and may be in contact with a portion of the third inner side surface SSF3.

A portion of the metal pattern MP may overlap at least a portion of the bank BMP in a plan view. The portion of the metal pattern MP may be disposed above the bank BMP. The portion of the metal pattern MP may be disposed on the top surface of the bank BMP. Each of the first to third metal patterns MP1, MP2, and MP3 may overlap at least a portion of the bank BMP in a plan view. A portion of each of the first to third metal patterns MP1, MP2, and MP3 may be disposed above the bank BMP. The portion of each of the first to third metal patterns MP1, MP2, and MP3 may be disposed on the top surface of the bank BMP. A portion of the first metal pattern MP1 may be in contact with the first inner side surface SSF1, and a portion of the first metal pattern MP1 may be in contact with a portion of the top surface of the bank BMP. A portion of the second metal pattern MP2 may be in contact with the second inner side surface SSF2, and a portion of the second metal pattern MP2 may be in contact with a portion of the top surface of the bank BMP. A portion of the third metal pattern MP3 may be in contact with the third inner side surface SSF3, and a portion of the third metal pattern MP3 may be in contact with a portion of the top surface of the bank BMP.

A portion of the metal pattern MP may overlap a portion of each of the light control patterns CCP-R, CCP-G, and CCP-B in a plan view. Portions of the metal patterns MP1, MP2, and MP3 may be disposed below the light control patterns CCP-R, CCP-G, and CCP-B, respectively. The portions of the metal patterns MP1, MP2, and MP3 may be disposed between the light control patterns CCP-R, CCP-G, and CCP-B and the second barrier layer CAP2. A portion of the first metal pattern MP1 may be disposed below the first light control pattern CCP-R. The portion of the first metal pattern MP1 may be disposed between the first light control pattern CCP-R and the second barrier layer CAP2. A portion of the second metal pattern MP2 may be disposed below the second light control pattern CCP-G. The portion of the second metal pattern MP2 may be disposed between the second light control pattern CCP-G and the second barrier layer CAP2. A portion of the third metal pattern MP3 may be disposed below the third light control pattern CCP-B. The portion of the third metal pattern MP3 may be disposed between the third light control pattern CCP-B and the second barrier layer CAP2. However, an embodiment is not limited thereto, and the metal pattern MP may be in contact with the inner side surfaces SSF1, SSF2, and SSF3, without overlapping the bank BMP or the light control patterns CCP-R, CCP-G, and CCP-B in a plan view.

The metal patterns MP1, MP2, and MP3 may include first portions M1a, M2a, and M3a disposed on the inner side surfaces SSF1, SSF2, and SSF3 of the bank BMP, second portions M1b, M2b, and M3b disposed above the bank BMP, and third portions M1c, M2c, and M3c disposed below the light control patterns CCP-R, CCP-G, and CCP-B, respectively. The first portions M1a, M2a, and M3a, the second portions M1b, M2b, and M3b, and the third portions M1c, M2c, and M3c may include the same material and may be formed using the same process.

The first metal pattern MP1 may include a (1-1)-th portion M1a disposed on the first inner side surface SSF1, a (1-2)-th portion M1b disposed on a surface of the bank BMP, and a (1-3)-th portion M1c disposed below the first light control pattern CCP-R. In the first metal pattern MP1, the (1-1)-th portion M1a may be a portion disposed between the first inner side surface SSF1 and the first light control pattern CCP-R. The (1-1)-th portion M1a, (1-2)-th portion M1b, and the (1-3)-th portion M1c may have a shape of one body (or a single continuous structure).

The second metal pattern MP2 may include a (2-1)-th portion M2a disposed on the second inner side surface SSF2, a (2-2)-th portion M2b disposed on a surface of the bank BMP, and a (2-3)-th portion M2c disposed below the second light control pattern CCP-G. In the second metal pattern MP2, the (2-1)-th portion M2a may be a portion disposed between the second inner side surface SSF2 and the second light control pattern CCP-G. The (2-1)-th portion M2a, (2-2)-th portion M2b, and the (2-3)-th portion M2c may have a shape of one body (or a single continuous structure).

The third metal pattern MP3 may include a (3-1)-th portion M3a disposed on the third inner side surface SSF3, a (3-2)-th portion M3b disposed on a surface of the bank BMP, and a (3-3)-th portion M3c disposed below the third light control pattern CCP-B. In the third metal pattern MP3, the (3-1)-th portion M3a may be a portion disposed between the third inner side surface SSF3 and the third light control pattern CCP-B. The (3-1)-th portion M3a, (3-2)-th portion M3b, and the (3-3)-th portion M3c may have a shape of one body (or a single continuous structure).

The bank BMP may include a top surface that connects the first to third inner side surfaces SSF1, SSF2, and SSF3 to each other. At least a portion of the top surface of the bank BMP may remain uncovered by the metal pattern MP. By leaving a portion of the top surface of the bank BMP exposed, the liquid-repellent properties of the surface may help further prevent overflow of the light control patterns CCP-R, CCP-G, and CCP-B. In a case in which the light control patterns CCP-R, CCP-G, and CCP-B are formed through a printing method such as an inkjet process, an ink may be in contact with the exposed top surface of the bank BMP, thereby enhancing overflow prevention of the light control patterns CCP-R, CCP-G, and CCP-B.

The metal pattern MP may include a reflective metal. The metal pattern MP may include a reflective metal having high reflectance. For example, the metal pattern MP may include Ag, Mg, Cu, Al, Pt, Pd, Au, Ni, Nd, Ir, Cr, Li, Ca, LiF/Ca, LiF/Al, Mo, Ti, W, In, Zn, Sn, or a compound or mixture thereof (e.g., a mixture of Ag and Mg), all of which have high reflectance.

The light control layer CCL may further include the first barrier layer CAP1 disposed on a surface of the light control patterns CCP-R, CCP-G, and CCP-B, and the second barrier layer CAP2 disposed on another surface of the light control patterns CCP-R, CCP-G, and CCP-B. The first barrier layer CAP1 may follow a stepped portion between the bank BMP and each of the light control patterns CCP-R, CCP-G, and CCP-B.

The light control layer CCL included in the display panel according to an embodiment may include the bank BMP which is optically transparent and may include the metal pattern MP disposed between the bank BMP and each of the light control patterns CCP-R, CCP-G, and CCP-B. The inclusion of the transparent bank BMP may expand the transmission area of the light emitted through the light control layer CCL. The metal pattern MP disposed between the bank BMP and each of the light control patterns CCP-R, CCP-G, and CCP-B may enhance the photoconversion efficiency of the light control patterns CCP-R, CCP-G, and CCP-B. As the open portions OP1, OP2, and OP3, which do not surround the light control patterns CCP-R, CCP-G, and CCP-B, are defined in the metal pattern MP, a critical dimension (CD) of the bank BMP may be minimized, thereby increasing an aperture ratio of the bank opening portions BOH1, BOH2, and BOH3 for the same surface area. Accordingly, the display panel including the light control layer CCL may have high resolution and improved display efficiency.

In a conventional display panel, metal patterns may have a closed-line shape that entirely surrounds a light control pattern in a plan view. A process of forming these metal patterns having the closed-line shape may require maintaining a process margin with a selected distance between the metal patterns to secure a liquid-repellent properties of a top surface of the bank BMP. However, in a case in which the critical dimension (CD) is reduced to increase the aperture ratio of the bank opening, maintaining the process margin may become challenging, potentially leading to defects caused by process deviations. Thus, using metal patterns having a closed-line shape may have limitations in achieving high-resolution display panels.

In an embodiment, the display panel may include metal patterns with open portions OP1, OP2, and OP3 which do not (completely) surround the light control patterns CCP-R, CCP-G, and CCP-B. This structure may allow the display panel to maintain sufficient distance between the metal patterns MP and secure the process margin, even in a case where the critical dimension (CD) of the bank BMP is reduced. As the display panel has the structure in which the open portions do not face each other, and the structure in which a metal pattern MP is disposed between adjacent light control patterns CCP-R, CCP-G, and CCP-B, color mixing between the light control patterns CCP-R, CCP-G, and CCP-B may be prevented, and also the efficiency of the light emitted to the outside may be improved. Accordingly, the display panel may achieve high resolution, high display efficiency, and improved reliability.

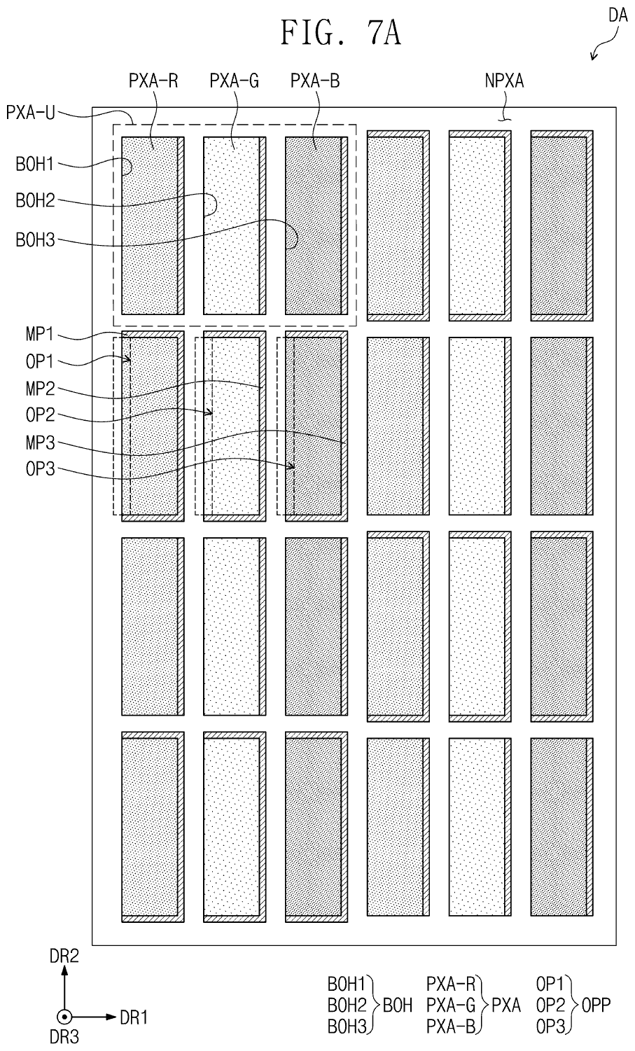

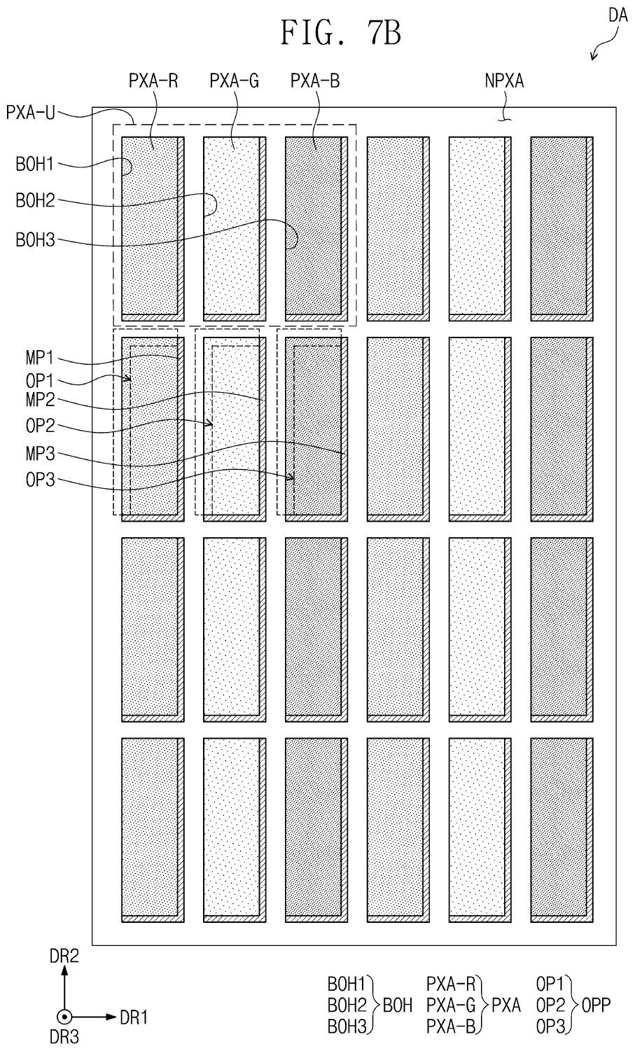

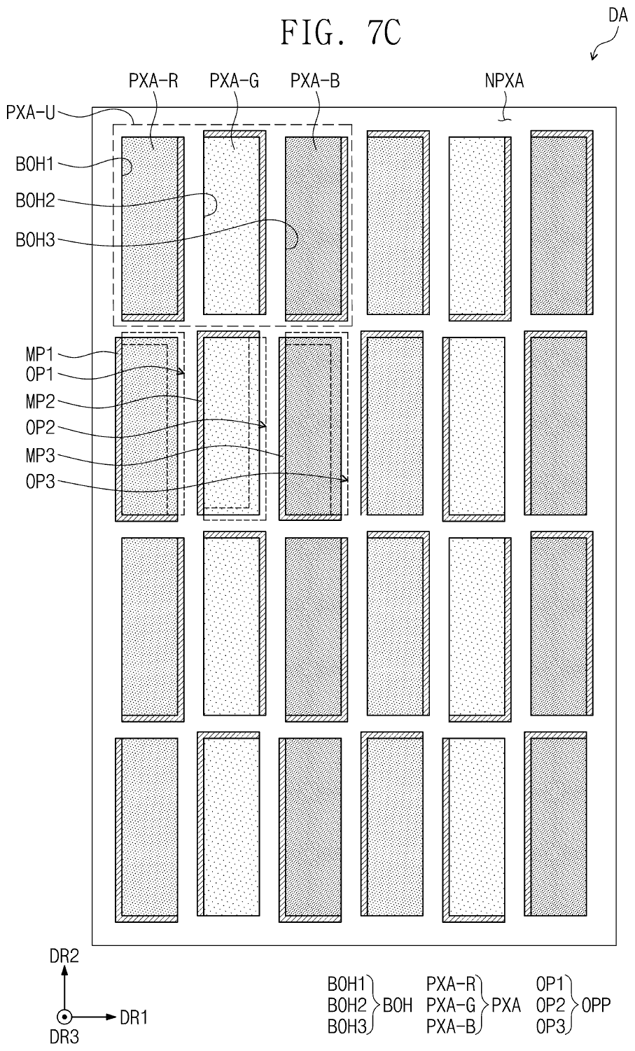

FIGS. 7A to 7C are enlarged schematic plan views of a portion of a display panel according to an embodiment. Hereinafter, the display panel according to an embodiment will be described with reference to FIGS. 7A to 7C while the same asor similar to components to those described above are designated with the same or similar reference numbers or symbols and are not set forth in detail.

A planar arrangement of metal patterns MP1, MP2, and MP3 included in the display panel illustrated in FIGS. 7A to 7C may be different from the planar arrangement of the metal patterns MP1, MP2, and MP3 included in the display panel illustrated in FIGS. 2A. The same contents of the metal patterns MP1, MP2, and MP3 described above with reference to FIGS. 2A to 6 may apply to the metal patterns MP1, MP2, and MP3 illustrated in FIGS. 7A to 7C, except that the planar arrangement is different.

As illustrated in FIGS. 7A to 7C, planar shapes and arrangement of the metal patterns MP1, MP2, and MP3 included in the display panel according to an embodiment may vary. In an embodiment, the metal patterns MP1, MP2, and MP3 may have various planar shapes such as straight line shapes including a vertical line (“|”) shape or a horizontal line (“-”) shape, as well as “┐” shape, reversed “┐” shape, “└” shape, reversed “└” shape, “⊏” shape, or reversed “⊏” shape. However, the planar shapes of the metal patterns MP1, MP2, and MP3 are not limited thereto.

Referring to FIGS. 7A to 7C, the metal pattern MP may be disposed between each of light control patterns CCP-R, CCP-G, and CCP-B and a bank BMP. The metal pattern MP may include a first metal pattern MP1 disposed between a first light control pattern CCP-R and the bank BMP, a second metal pattern MP2 disposed between a second light control pattern CCP-G and the bank BMP, and a third metal pattern MP3 disposed between a third light control pattern CCP-B and the bank BMP.

The metal pattern MP may surround a portion of each of the light control patterns CCP-R, CCP-G, and CCP-B in a plan view. The first metal pattern MP1 may surround a portion of the first light control pattern CCP-R, the second metal pattern MP2 may surround a portion of the second light control pattern CCP-G, and the third metal pattern MP3 may surround the third light control pattern CCP-B in a plan view.

Open portions OP1, OP2, and OP3, which do not surround the light control patterns CCP-R, CCP-G, and CCP-B, respectively, may be defined in the metal pattern MP. A first open portion OP1 which does not surround the first light control pattern CCP-R may be defined in the first metal pattern MP1, a second open portion OP2 which does not surround the second light control pattern CCP-G may be defined in the second metal pattern MP2, and a third open portion OP3 which does not surround the third light control pattern CCP-B may be defined in the third metal pattern MP3. The first to third open portions OP1, OP2, and OP3 may not face each other in a plan view.

A metal pattern may be disposed between adjacent light control patterns CCP-R, CCP-G, and CCP-B. For example, as illustrated in FIG. 7A, the second metal pattern MP2 may be disposed between the first light control pattern CCP-R and the second light control pattern CCP-G, the third metal pattern MP3 may be disposed between the second light control pattern CCP-G and the third light control pattern CCP-B, and the first metal pattern MP1 may be disposed between the third light control pattern CCP-B and the first light control pattern CCP-R.

Referring to FIG. 7A, the planar shapes of the first metal pattern MP1, the second metal pattern MP2, and the third metal pattern MP3 which are included in one pixel unit PXA-U may be the same. The planar shapes of the first to third metal patterns MP1, MP2, and MP3 which are included in the pixel unit PXA-U may be different, respectively, from the planar shapes of the first to third metal patterns MP1, MP2, and MP3 which are included in an adjacent pixel unit PXA-U. For example, the planar shape of the first metal pattern MP1 included in the pixel unit PXA-U may be different from the planar shape of the first metal pattern MP1 included in the adjacent pixel unit PXA-U. Likewise, the planar shapes of the second metal pattern MP2 and the third metal pattern MP3 included in the pixel unit PXA-U may be different, respectively, from the planar shapes of the second metal pattern MP2 and the third metal pattern MP3 included in the adjacent pixel unit PXA-U.

In an embodiment, on the basis of pixel units included in the same row group, in a case where first to third metal patterns MP1, MP2, and MP3 included in a pixel unit PXA-U disposed in a n-th row are defined as a first metal pattern group, and first to third metal patterns MP1, MP2, and MP3 included in a pixel unit PXA-U disposed in a (n+1)-th row are referred to as a second metal pattern group, the planar shapes of the first to third metal patterns MP1, MP2, and MP3 included in the first metal pattern group may be different, respectively, from the planar shapes of the first to third metal patterns MP1, MP2, and MP3 included in the second metal pattern group. Here, n is a natural number equal to or greater than 1. Each of the first to third metal patterns MP1, MP2, and MP3 included in the first metal pattern group may have one of a “|” shape or a reversed “⊏” shape, and the first to third metal patterns MP1, MP2, and MP3 included in the second metal pattern group may have another of a “|” shape or a reversed “⊏” shape.

Referring to FIG. 7B, planar shapes of the first metal pattern MP1, the second metal pattern MP2, and the third metal pattern MP3 which are included in a pixel unit PXA-U may be the same. The planar shapes of the first to third metal patterns MP1, MP2, and MP3 which are included in the pixel unit PXA-U may be the same, respectively, as the planar shapes of the first to third metal patterns MP1, MP2, and MP3 which are included in an adjacent pixel unit PXA-U. For example, the planar shape of the first metal pattern MP1 included in the pixel unit PXA-U may be the same as the planar shape of the first metal pattern MP1 included in the adjacent pixel unit PXA-U. Likewise, the planar shapes of the second metal pattern MP2 and the third metal pattern MP3 included in the pixel unit PXA-U may be the same, respectively, as the planar shapes of the second metal pattern MP2 and the third metal pattern MP3 included in the adjacent pixel unit PXA-U. In an embodiment, the first metal pattern MP1, the second metal pattern MP2, and the third metal pattern MP3 may each have a reversed “└” shape in a plan view.

A metal pattern may be disposed between adjacent light control patterns CCP-R, CCP-G, and CCP-B. For example, as illustrated in FIG. 7B, the second metal pattern MP2 may be disposed between the first light control pattern CCP-R and the second light control pattern CCP-SD-241208-ROD 61 G, the third metal pattern MP3 may be disposed between the second light control pattern CCP-G and the third light control pattern CCP-B, and the first metal pattern MP1 may be disposed between the third light control pattern CCP-B and the first light control pattern CCP-R.

Referring to FIG. 7C, the planar shape of at least one of the first metal pattern MP1, the second metal pattern MP2, or the third metal pattern MP3 which are included in a pixel unit PXA-U may be different from the planar shapes of the others. For example, on the basis of a pixel unit PXA-U, the planar shapes of the first metal pattern MP1 and the third metal pattern MP3 may be the same, and the planar shape of the second metal pattern MP2 may be different from those of the first metal pattern MP1 and the third metal pattern MP3. The planar shapes of the first to third metal patterns MP1, MP2, and MP3 which are included in the pixel unit PXA-U may be different, respectively, from the planar shapes of the first to third metal patterns MP1, MP2 and MP3 which are included in an adjacent pixel unit PXA-U. For example, the planar shape of the first metal pattern MP1 included in the pixel unit PXA-U may be different from the planar shape of the first metal pattern MP1 included in the adjacent pixel unit PXA-U. Likewise, the planar shapes of the second metal pattern MP2 and the third metal pattern MP3 included in the pixel unit PXA-U may be different, respectively, from the planar shapes of the second metal pattern MP2 and the third metal pattern MP3 included in the adjacent pixel unit PXA-U. In an embodiment, the shapes of the first metal pattern MP1, the second metal pattern MP2, and the third metal pattern MP3 may include a combination of a “└” shape, a reversed “└” shape, a “┐” shape, and a reversed “┐” shape.

In an embodiment, on the basis of pixel units included in the same row group, in a case where first to third metal patterns MP1, MP2, and MP3 included in a pixel unit PXA-U disposed in a n-th row may form a first metal pattern group, and first to third metal patterns MP1, MP2, and MP3 included in a pixel unit PXA-U disposed in a (n+1)-th row may form a second metal pattern group, the planar shapes of the first to third metal patterns MP1, MP2, and MP3 included in the first metal pattern group may be different, respectively, from the planar shapes of the first to third metal patterns MP1, MP2, and MP3 included in the second metal pattern group.

One metal pattern may be disposed between adjacent light control patterns CCP-R, CCP-G, and CCP-B. For example, as illustrated in FIG. 7C, the second metal pattern MP2 may be disposed between the first light control pattern CCP-R and the second light control pattern CCP-G, the third metal pattern MP3 may be disposed between the second light control pattern CCP-G and the third light control pattern CCP-B, and the first metal pattern MP1 may be disposed between the third light control pattern CCP-B and the first light control pattern CCP-R.

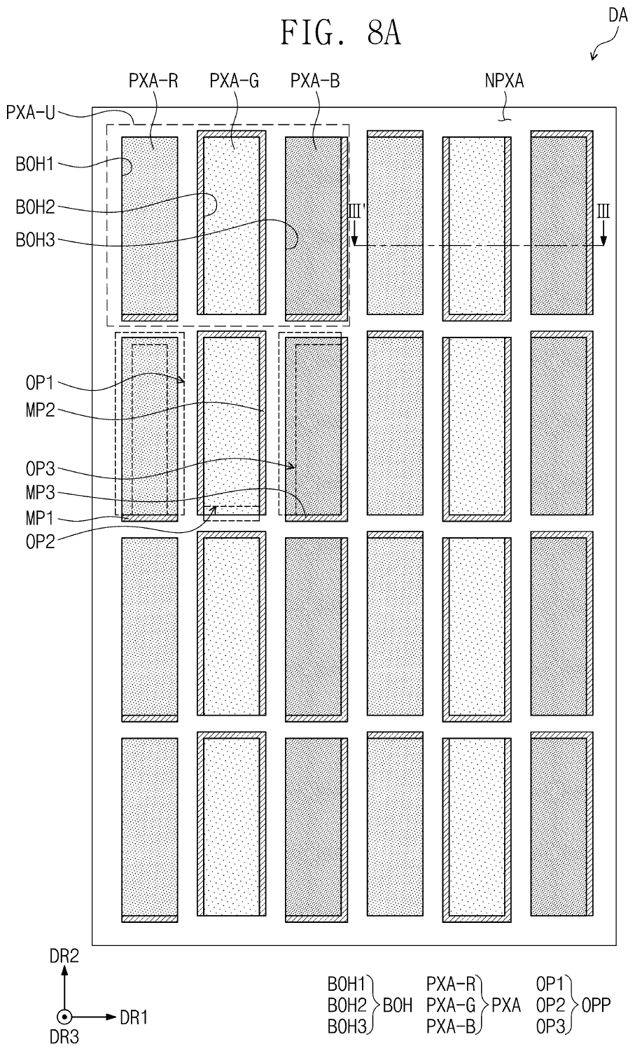

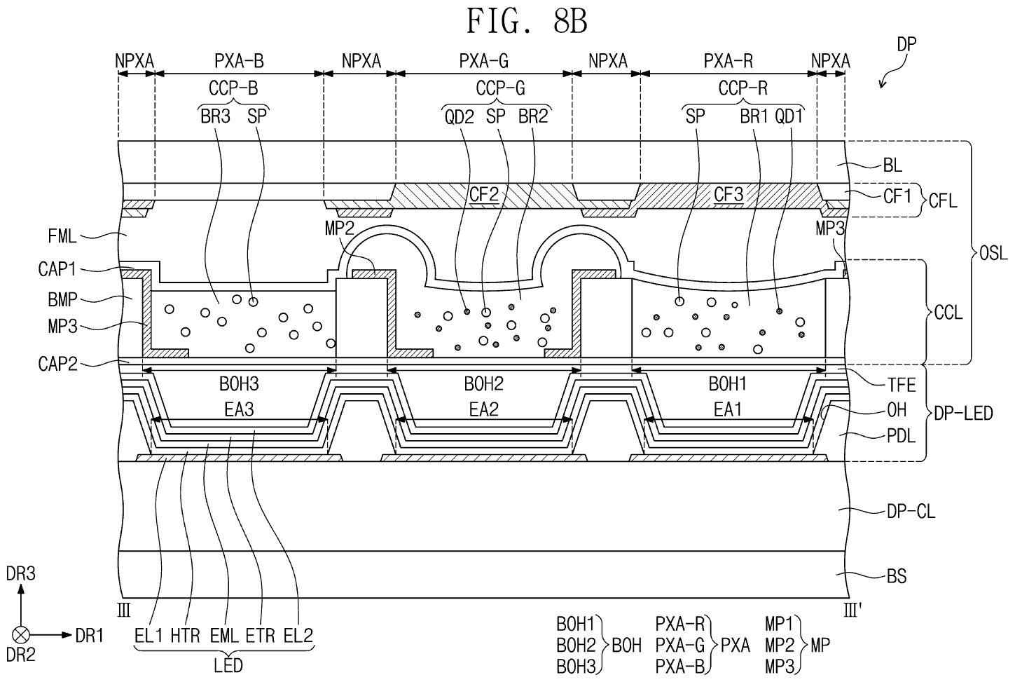

FIG. 8A is an enlarged schematic plan view of a portion of a display panel according to an embodiment. FIG. 8B is a schematic cross-sectional view of a portion of a display panel according to an embodiment. FIG. 8B illustrates a cross-section taken along line III-III′ illustrated in FIG. 8A. Hereinafter, the display panel according to an embodiment will be described with reference to FIGS. 8A and 8B, where the same or similar components as described above are designated by the same or similar reference numbers or symbols and are not set forth in detail.

A planar arrangement of metal patterns MP1, MP2, and MP3 included in the display panel illustrated in FIGS. 8A and 8B may be different from the planar arrangement of the metal patterns MP1, MP2, and MP3 included in the display panel illustrated in FIGS. 2A. The same contents of the metal patterns MP1, MP2, and MP3 described above with reference to FIGS. 2A to 6 may apply to the metal patterns MP1, MP2, and MP3 illustrated in FIGS. 8A and 8B, except that the planar arrangement is different.

Referring to FIG. 8A, among light control patterns CCP-R, CCP-G, and CCP-B, a first light control pattern CCP-R corresponding to a red pixel area and a second light control pattern CCP-G corresponding to a green pixel area may be formed through an inkjet process. Among the light control patterns CCP-R, CCP-G, and CCP-B, a third light control pattern CCP-B corresponding to a blue pixel area may be formed through a photoresist process.

In a plan view, a first metal pattern MP1 may surround a portion of the first light control pattern CCP-R, a second metal pattern MP2 may surround a portion of the second light control pattern CCP-G, and a third metal pattern MP3 may surround the third light control pattern CCP-B. A first open portion OP1 which does not surround the first light control pattern CCP-R may be defined in the first metal pattern MP1, a second open portion OP2 which does not surround the second light control pattern CCP-G may be defined in the second metal pattern MP2, and a third open portion OP3 which does not surround the third light control pattern CCP-B may be defined in the third metal pattern MP3.

In a metal pattern corresponding to one of the first light control pattern CCP-R and the second light control pattern CCP-G, each of which is formed through the inkjet process, an open portion may be formed so as to be adjacent to all of other pixel areas adjacent to a corresponding pixel area. For example, as illustrated in FIG. 8A, in the first metal pattern MP1 corresponding to the first light control pattern CCP-R, the first open portion OP1 may be formed so as to be adjacent to a second pixel area PXA-G and a third pixel area PXA-B. As an exposed area of a bank BMP is increased due to the first open portion OP1, an overflow phenomenon of an ink composition between adjacent pixels may be further prevented during the inkjet process. For example, as the first open portion OP1 is defined so as to be adjacent to all the other pixel areas PXA-G and PXA-B, the exposed area of the bank BMP may be increased, thereby further preventing ink overflow between the adjacent pixels.

Unlike the embodiment illustrated in FIG. 8A, in the second metal pattern MP2 corresponding to the second light control pattern CCP-G, the second open portion OP2 may be formed so as to be adjacent to the first pixel area PXA-R and the third pixel arca PXA-B. As the exposed area of the bank BMP increases due to the second open portion OP2, the overflow of the ink composition between the adjacent pixels may be further prevented during the inkjet process. For example, as the second open portion OP2 is defined so as to be adjacent to all the other pixel areas PXA-G and PXA-B, the exposed area of the bank BMP may be increased, further preventing ink overflow between the adjacent pixels.

On the basis of the first direction DR1 in which the first to third pixel areas PXA-R, PXA-G, and PXA-B are arranged, the first open portion OP1 corresponding to the first light control pattern CCP-R may be adjacent to each of the adjacent second light control pattern CCP-G and the adjacent third light control pattern CCP-B. For example, as illustrated in FIG. 8A, the first open portion OP1 may be adjacent to each of two long sides of the first light control pattern CCP-R extending in the second direction DR2 and spaced apart from each other in the first direction DR1. On the basis of the first direction DR1 in which the first to third pixel areas PXA-R, PXA-G, and PXA-B are arranged, the second metal pattern MP2 may be disposed between the first light control pattern CCP-R and the second light control pattern CCP-G adjacent thereto, and the third metal pattern MP3 may be disposed between the second light control pattern CCP-G and the third light control pattern CCP-B adjacent thereto.

However, an embodiment is not limited thereto, and, unlike the embodiment illustrated in FIG. 8A, on the basis of the first direction DR1 in which the first to third pixel areas PXA-R, PXA-G, and PXA-B are arranged, the second open portion OP2 corresponding to the second light control pattern CCP-G may be adjacent to each of the adjacent first light control pattern CCP-R and the adjacent third light control pattern CCP-B. For example, the second open portion OP2 may be adjacent to each of two long sides which extends from the second light control pattern CCP-G in the second direction DR2 and are spaced apart from each other in the first direction DRI. On the basis of the first direction DR1 in which the first to third pixel areas PXA-R, PXA-G and PXA-B are arranged, the first metal pattern MP1 may be disposed between the second light control pattern CCP-G and the adjacent first light control pattern CCP-R, and the third metal pattern MP3 may be disposed between the second light control pattern CCP-G and the adjacent third light control pattern CCP-B.

In an embodiment, the second metal pattern MP2 may be disposed between the first light control pattern CCP-R and the second light control pattern CCP-G, the second metal pattern MP2 may be disposed between the second light control pattern CCP-G and the third light control pattern CCP-B, and the third metal pattern MP3 may be disposed between the third light control pattern CCP-B and the first light control pattern CCP-R. The first open portion OP1 may be defined in the first metal pattern MP1 corresponding to the first light control pattern CCP-R, and the first open portion OP1 may face the second metal pattern MP2 and the third metal pattern MP3 in the first direction DR1.

However, an embodiment is not limited thereto, and, unlike the embodiment illustrated in FIG. 8A, the first metal pattern MP1 may be disposed between the first light control pattern CCP-R and the second light control pattern CCP-G, the third metal pattern MP3 may be disposed between the second light control pattern CCP-G and the third light control pattern CCP-B, and the first metal pattern MP1 may be disposed between the third light control pattern CCP-B and the first light control pattern CCP-R. The second open portion OP2 may be defined in the second metal pattern MP2 corresponding to the second light control pattern CCP-G, and the second open portion OP2 may face the first metal pattern MP1 and the third metal pattern MP3 in the first direction DR1.

In an embodiment, one of the first metal pattern MP1 and the second metal pattern MP2 may have a “-” shape, and the other may have a “⊏” shape rotated 90 degrees either clockwise or counter-clockwise.

When viewed in the first direction, the first metal pattern MP1 and the second metal pattern MP2 may not overlap each other. For example, as illustrated in FIG. 8A, when viewed in the first direction, the first metal pattern MP1 and the second metal pattern MP2 may not overlap each other.

According to the embodiment, the metal pattern made of the reflective metal may be disposed between the optically transparent bank and the light control pattern. The metal pattern may include an open portion which does not surround the light control pattern. Accordingly, the photoconversion efficiency of the light control layer may be improved, and also, the wide aperture ratio of the bank may be maintained. Thus, the display panel including the light control layer may have high resolution and improved display efficiency.

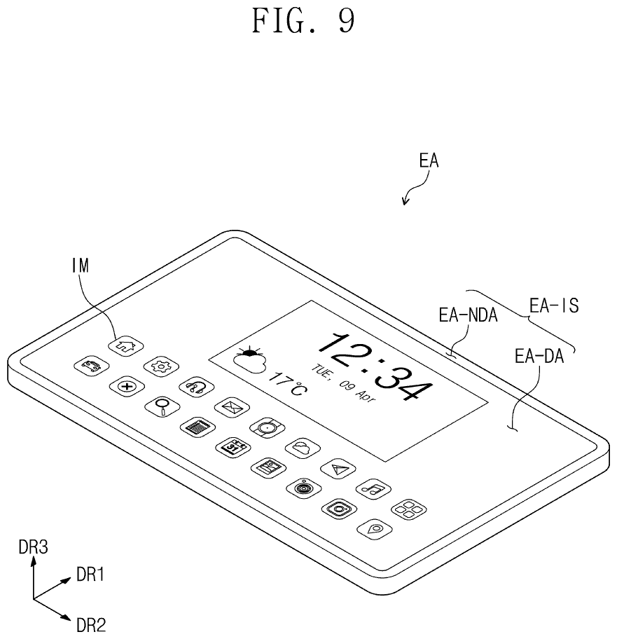

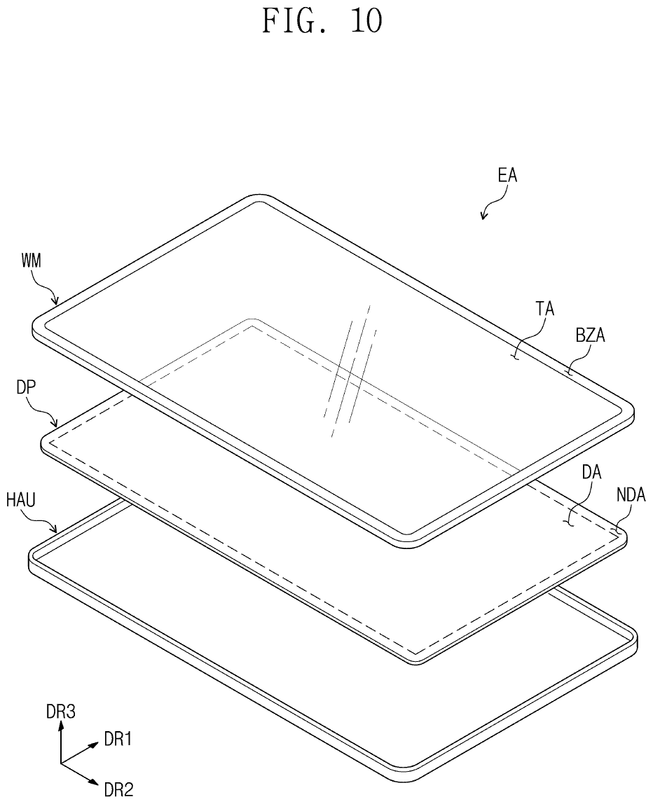

FIG. 9 illustrates a schematic perspective view showing an electronic device according to an embodiment. FIG. 10 illustrates an exploded schematic perspective view showing an electronic device according to an embodiment.

The electronic device EA may display an image IM through a display surface EA-IS. The image IM may include a dynamic image as well as a static image. The display surface EA-IS may be parallel to a plane defined by a first direction DR1 and a second direction DR2. FIG. 9 illustrates an electronic device EA having a flat display surface EA-IS, but an embodiment is not limited thereto. For example, the electronic device EA may include a curved display surface or a three-dimensional display surface. The three-dimensional display surface may include multiple display areas oriented in different directions.

The display surface EA-IS may include an active area EA-DA and a peripheral arca EA-NDA. The electronic device EA may display an image IM through the active arca EA-DA.

The peripheral area EA-NDA may have a selected color. The peripheral area EA-NDA may be adjacent to the active area EA-DA. The peripheral area EA-NDA may surround the active arca EA-DA. Accordingly, the shape of the active area EA-DA may be defined by the peripheral area EA-NDA. However, FIG. 9 is a schematic illustration, and the peripheral area EA-NDA may be disposed adjacent to only one side of the active area EA-DA or may be omitted.

Referring to FIG. 10, the electronic device EA may include a display panel DP. The electronic device EA may further include a window member WM and a housing HAU.

The window member WM may cover the outer side of the electronic device EA. The window member WM may include a transparent area TA and a bezel area BZA. The front surface of the window member WM including the transparent area TA and the bezel area BZA may correspond to the front surface of the electronic device EA. The transparent area TA may correspond to the active area EA-DA of the electronic device EA illustrated in FIG. 9, and the bezel area BZA may correspond to the peripheral area EA-NDA of the electronic device EA illustrated in FIG. 9.

The transparent area TA may be an optically transparent. The bezel area BZA may have lower light transmittance compared to the transparent area TA. The bezel area BZA may have a selected color. The bezel area BZA may be adjacent to the transparent area TA and may surround the transparent area TA. The bezel area BZA may define the shape of the transparent area TA. However, an embodiment is not limited thereto, and the bezel area BZA may be adjacent to only one side of the transparent area TA, or a portion of the bezel area BZA may be omitted.

The housing HAU may include a material having relatively high rigidity. For example, the housing HAU may include a frame and/or a plate made of glass, plastic, or metal. The frames and/or plates may be provided in multiple pieces. The housing HAU may provide a selected receiving space. The display panel DP may be accommodated in the receiving space and protected from external impact.

The display panel DP may include the same configurations as the display panel DP described in the embodiments referenced in FIGS. 1A to 1C.

A display area DA and a non-display area NDA may be defined in the display panel DP. The display area DA may overlap the active area EA-DA illustrated in FIG. 9, and the non-display area NDA may overlap the peripheral area EA-NDA illustrated in FIG. 9.

The display area DA may correspond to a region that is activated in response to an electrical signal. The non-display area NDA may be positioned adjacent to at least one side of the display area DA. The display area DA may include the non-light emitting area NPXA and pixel areas PXA-R, PXA-G, and PXA-B, illustrated in FIG. 2A. The non-display area NDA may be disposed to surround the display area DA. However, an embodiment is not limited thereto, and portions of the non-display area NDA may be omitted. A driving circuit or driving wiring that controls the display area DA may be disposed in the non-display area NDA.

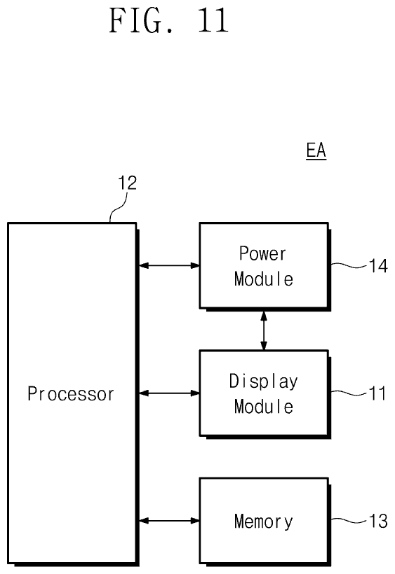

The electronic device EA according to an embodiment may include the display panel described above and may further include a module or device having an additional function, in addition to the display panel. For example, an electronic device according to an embodiment may include the display panel and further include additional module or device that provides supplementary functions. FIG. 11 is a schematic block diagram of an electronic device according to an embodiment. Referring to FIG. 11, an electronic device EA according to an embodiment may include a display module 11, a processor 12, a memory 13, and a power module 14.

The processor 12 may include one or more components, such as a central processing unit (CPU), an application processor (AP), a graphic processing unit (GPU), a communication processor (CP), an image signal processor (ISP), or a controller.

The memory 13 may store data information required for an operation of the processor 12 or the display module 11. In a case where the processor 12 executes an application stored in the memory 13, an image data signal and/or an input control signal may be transmitted to the display module 11, and the display module 11 may process the provided signal and output image information on a display screen.

The power module 14 may include a power supply module such as a power adapter or a battery device, and a power conversion module which converts the supplied power to generate the required power for operating the electronic device EA.

At least one of the components of the electronic device EA described above may be included in the display panel as described in the embodiments above. Some module, which may function as part of an integrated module, may be included in the display panel, and others may be provided separately from the display panel. For example, the display panel may include the display module 11, and the processor 12, the memory 13, and the power module 14 may be included in another component of the electronic device EA rather than in the display panel itself.

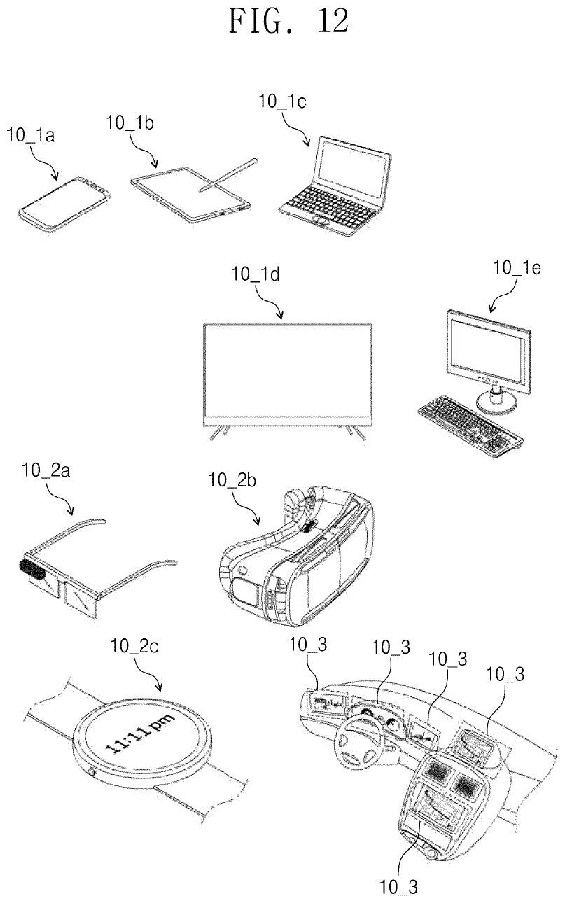

FIG. 12 illustrates schematic views of electronic devices according to various embodiments.

Referring to FIG. 12, various electronic devices to which the display panel according to an embodiment is applied may include, for example, electronic devices for displaying images, e.g., a smartphone 10_1a, a tablet computer (PC) 10_1b, a laptop computer 10_1c, TV 10_1d, and a monitor for a desk computer 10_1e. The display panel may also be included in wearable electronic devices including display modules, e.g., smart glasses 10_2a, a head mounted display 10_2b, and a smart watch 10_2c. Vehicle electronic devices 10_3 including display modules may include components, e.g., a vehicle instrument panel, a center fascia, a center information display (CID) disposed on a dashboard, and a room mirror display.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the following claims.

What is claimed is:

1. A display panel comprising:
a display element layer comprising a light emitting element which outputs source light; and
an optical structure layer disposed on the light emitting element, which transmits the source light or converts the source light to light having a different wavelength range, wherein
the optical structure layer comprises a light control layer disposed on the light emitting element, the light control layer comprising:
a bank defining a bank opening portion;
a light control pattern disposed in the bank opening portion; and
a metal pattern disposed between the bank and the light control pattern, wherein
the bank is optically transparent,
the metal pattern surrounds a portion of the light control pattern, and
the metal pattern defines an open portion which does not surround the light control pattern.

2. The display panel of claim 1, wherein the bank comprises a material having a transmittance of about 85% or more in a visible light range.

3. The display panel of claim 1, wherein the light control pattern in the open portion is in contact with at least a portion of the bank.

4. The display panel of claim 1, wherein the metal pattern comprises:
a first portion disposed on an inner side surface of the bank; and
a second portion extending from the first portion and covering at least a portion of an upper surface of the bank.

5. The display panel of claim 1, wherein
the bank opening portion comprises a first bank opening portion and a second bank opening portion which are adjacent to each other in a first direction, and
the light control pattern comprises:
a first light control pattern disposed in the first bank opening portion; and
a second light control pattern disposed in the second bank opening portion.

6. The display panel of claim 5, wherein
the metal pattern comprises:
a first metal pattern disposed between the bank and the first light control pattern, which surrounds a portion of the first light control pattern; and
a second metal pattern disposed between the bank and the second light control pattern, which surrounds a portion of the second light control pattern,
the first metal pattern defines a first open portion which does not surround the first light control pattern, and
the second metal pattern defines a second open portion which does not surround the second light control pattern.

7. The display panel of claim 6, wherein the first open portion and the second open portion do not face each other in the first direction.

8. The display panel of claim 6, wherein, between the first light control pattern and the second light control pattern,
the first open portion and at least a portion of the second metal pattern face each other, or the second open portion and at least a portion of the first metal pattern face each other.

9. The display panel of claim 6, wherein
in the first open portion, the first light control pattern is in contact with at least a portion of the bank, and
in the second open portion, the second light control pattern is in contact with at least a portion of the bank.

10. The display panel of claim 6, wherein one of the first metal pattern and the second metal pattern is disposed between the first light control pattern and the second light control pattern.

11. The display panel of claim 5, wherein
a first bank area defined by the first bank opening portion emits light having a first wavelength,
a second bank area defined by the second bank opening portion emits light having a second wavelength, and
the second wavelength is shorter than the first wavelength.

12. The display panel of claim 5, wherein
the bank opening portion further comprises a third bank opening portion adjacent to the second bank opening portion in the first direction,
the light control layer further comprises a third light control pattern disposed in the third bank opening portion, and
the metal pattern comprises:
a first metal pattern disposed between the bank and the first light control pattern, which surrounds a portion of the first light control pattern;
a second metal pattern disposed between the bank and the second light control pattern, which surrounds a portion of the second light control pattern; and
a third metal pattern disposed between the bank and the third light control pattern, which surrounds a portion of the third light control pattern,
the first metal pattern defines a first open portion which does not surround the first light control pattern,
the second metal pattern defines a second open portion which does not surround the second light control pattern, and
the third metal pattern defines a third open portion which does not surround the third light control pattern.

13. The display panel of claim 12, wherein
one of the first metal pattern and the second metal pattern is disposed between the first light control pattern and the second light control pattern,
one of the second metal pattern and the third metal pattern is disposed between the second light control pattern and the third light control pattern, and
one of the third metal pattern and the first metal pattern is disposed between the third light control pattern and the first light control pattern.

14. The display panel of claim 12, wherein
the second metal pattern is disposed between the first light control pattern and the second light control pattern,
the second metal pattern is disposed between the second light control pattern and the third light control pattern, and
the third metal pattern is disposed between the third light control pattern and the first light control pattern.

15. The display panel of claim 14, wherein
each of the first light control pattern and the second light control pattern comprises a base resin and a quantum dot dispersed in the base resin, and
the first light control pattern comprises a photosensitive resin.

16. The display panel of claim 12, wherein
the optical structure layer further comprises a color filter layer disposed on the light control layer and comprising a first color filter, a second color filter, and a third color filter,
the first color filter overlaps at least the first light control pattern,
the second color filter overlaps at least the second light control pattern, and
the third color filter overlaps at least the third light control pattern.

17. The display panel of claim 12, wherein the light control layer further comprises a first barrier layer which covers a surface of each of the first light control pattern, the second light control pattern, and the third light control pattern.

18. The display panel of claim 1, wherein
the display element layer further comprises an encapsulation layer which covers the light emitting element, and
the light control layer is directly disposed on the encapsulation layer.

19. A display panel comprising:
a display element layer comprising a light emitting element which outputs source light; and
an optical structure layer disposed on the light emitting element, which transmits the source light or converts the source light to light having a different wavelength range, wherein
the optical structure layer comprises a light control layer disposed on the light emitting element,
the light control layer comprises:
a bank comprising a first bank opening portion and a second bank opening portion which are adjacent to each other in a first direction;
a first light control pattern disposed in the first bank opening portion;
a second light control pattern disposed in the second bank opening portion;
a first metal pattern disposed between the bank and the first light control pattern; and
a second metal pattern disposed between the bank and the second light control pattern, wherein.
the bank comprises a first inner side surface which defines the first bank opening portion, and a second inner side surface which defines the second bank opening portion,
the first metal pattern defines a first open portion which exposes at least a portion of the first inner side surface,
the second metal pattern defines a second open portion which exposes at least a portion of the second inner side surface, and
The first open portion and the second open portion do not face each other.

20. An electronic device providing an image, the electronic device comprising:
a window;
a display panel disposed below the window; and
a housing disposed below the display panel and coupled with the window to accommodate the display panel, the display panel comprising:
a display element layer comprising a light emitting element which outputs source light; and
an optical structure layer disposed on the light emitting element, which transmits the source light or converts the source light to light having a different wavelength range, wherein.
the optical structure layer comprises a light control layer disposed on the light emitting element, the light control layer comprising:
a bank defining a bank opening portion;
a light control pattern disposed in the bank opening portion; and
a metal pattern disposed between the bank and the light control pattern,
the bank is optically transparent,
the metal pattern surrounds a portion of the light control pattern, and
the metal pattern defines an open portion which does not surround the light control pattern.
